(19) United States
(12) Patent Application Publication
(10) Pub. No.: US 2026/0122900 A1
(43) Pub. Date: Apr. 30, 2026

(54) SEMICONDUCTOR MEMORY DEVICE AND ELECTRONIC SYSTEM INCLUDING THE SAME

(71) Applicants: Samsung Electronics Co., Ltd., Suwon-si (KR); Research & Business Foundation SUNGKYUNKWAN UNIVERSITY, Suwon-si (KR)

(72) Inventors: Choa Sub KIM, Suwon-si (KR); Hyoung Sub KIM, Seoul-si (KR); Yong Kyu LEE, Suwon-si (KR); Jong-Wook JEON, Suwon-si (KR)

(73) Assignees: Samsung Electronics Co., Ltd., Suwon-si (KR); Research & Business Foundation SUNGKYUNKWAN UNIVERSITY, Suwon-si (KR)

(21) Appl. No.: 19/321,501

(22) Filed: Sep. 8, 2025

(30) Foreign Application Priority Data
Oct. 31, 2024 (KR) 10-2024-0151816

(51) Int. Cl. H10B 43/35; H10B 43/27

(52) U.S. Cl. CPC H10B 43/35; H10B 43/27

(57) ABSTRACT

Provided is a semiconductor memory device. The semiconductor memory device includes a substrate, a stack structure disposed on the substrate, wherein the stack structure includes a plurality of gate electrodes and a plurality of insulating layers alternately stacked on top of each other in a first direction perpendicular to an upper surface of the substrate, a channel structure extending through the stack structure and extending in the first direction, and a bit line connected to the channel structure via a contact plug disposed on the channel structure, wherein the channel structure includes a core insulating layer, a channel layer disposed on a side surface of the core insulating layer, a channel insulating layer extending in the first direction to be disposed between the channel layer and the plurality of gate electrodes, and a channel pad disposed on top of the core insulating layer to be in contact with the channel layer, wherein the channel pad includes a first pad layer including a material of a first conductivity, and a second pad layer disposed on top of the first pad layer in the first direction and including a material of a second conductivity different from the first conductivity, wherein an outermost side surface of the second pad layer is in contact with the channel insulating layer.

### CROSS-REFERENCE TO RELATED APPLICATION

This U.S. non-provisional application claims priority from Korean Patent Application No. 10-2024-0151816 filed on Oct. 31, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor memory device and an electronic system including the same.

### Description of Related Art

In order to meet high performance and low price of a semiconductor memory device as demanded by consumers, increasing integration of the semiconductor memory device is required. Integration of semiconductor memory devices is an important factor in determining a price thereof. Thus, semiconductor memory devices having increased integration is particularly required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase is limited. Accordingly, three-dimensional semiconductor memory devices including three-dimensionally arranged memory cells have been proposed.

### SUMMARY

A technical purpose that the present disclosure seeks to achieve is to provide a semiconductor memory device with improved electrical characteristics and reliability.

Another technical purpose that the present disclosure seeks to achieve is to provide an electronic system including a semiconductor memory device with improved electrical characteristics and reliability.

A semiconductor memory device according to some embodiments of the present disclosure for achieving the above technical object includes a substrate, a stack structure disposed on the substrate, wherein the stack structure includes a plurality of gate electrodes and a plurality of insulating layers each gate electrode of the plurality of gate electrodes and insulating layer of the plurality of insulating layers being alternately stacked on top of each other in a first direction perpendicular to an upper surface of the substrate, a channel structure extending through the stack structure and extending in the first direction, and a bit line connected to the channel structure via a contact plug disposed on the channel structure, wherein the channel structure includes a core insulating layer, a channel layer disposed on a side surface of the core insulating layer, a channel insulating layer extending in the first direction to be disposed between the channel layer and the plurality of gate electrodes, and a channel pad disposed on top of the core insulating layer to be in contact with the channel layer, wherein the channel pad includes a first pad layer including a material of a first conductivity, and a second pad layer disposed on top of the first pad layer in the first direction and including a material of a second conductivity different from the first conductivity, wherein an outermost side surface of the second pad layer is in contact with the channel insulating layer.

A semiconductor memory device according to some other embodiments of the present disclosure for achieving the above technical object includes a substrate, a stack structure disposed on the substrate, wherein the stack structure includes a plurality of gate electrodes and a plurality of insulating layers each gate electrode of the plurality of gate electrodes and insulating layer of the plurality of insulating layers being alternately stacked on top of each other in a vertical direction, a channel structure extending through the stack structure and extending in the vertical direction, and a bit line connected to the channel structure via a contact plug disposed on the channel structure, wherein the channel structure includes a core insulating layer, a channel layer disposed on a side surface of the core insulating layer, a channel insulating layer extending in the vertical direction to be disposed between the channel layer and the plurality of gate electrodes, and a channel pad disposed on top of the core insulating layer to be in contact with the channel layer, wherein the channel pad includes a first pad layer including polysilicon doped having a first conductivity impurity, a second pad layer disposed on top of the first pad layer and including polysilicon doped having a second conductivity different from the first conductivity, and a first polysilicon layer disposed between the first and second pad layers, wherein the first polysilicon layer is not doped with an impurity, and wherein a side surface of the first pad layer is not in contact with the second pad layer.

A semiconductor memory device according to some other embodiments of the present disclosure for achieving the above technical object includes a peripheral circuit structure disposed on a semiconductor substrate and including circuit elements, a pattern structure disposed on the peripheral circuit structure, wherein the pattern structure includes a lower pattern layer, a middle pattern layer disposed on the lower pattern layer and including an impurity of a first conductivity, and an upper pattern layer disposed on the middle pattern layer, a stack structure disposed on the pattern structure, wherein the stack structure includes a plurality of gate electrodes and a plurality of insulating layers each gate electrode of the plurality of gate electrodes and insulating layer of the plurality of insulating layers being alternately stacked on top of each other in a vertical direction, a channel structure extending through the stack structure and extending in the vertical direction, and a bit line connected to the channel structure via a contact plug disposed on the channel structure, wherein the channel structure includes a core insulating layer, a channel layer disposed on a side surface of the core insulating layer, a channel insulating layer extending in the vertical direction to be disposed between the channel layer and the plurality of gate electrodes, and a channel pad disposed on top of the core insulating layer to be in contact with the channel layer, wherein the channel pad includes a first pad layer including an impurity of a second conductivity different from the impurity of the first conductivity, a second pad layer disposed on top of the first pad layer in the vertical direction, wherein the second pad layer includes an impurity of the first conductivity, and a first polysilicon layer disposed between the first and second pad layers, wherein the first polysilicon layer is not doped with an impurity, and wherein an outermost side surface of the second pad layer is in contact with the channel insulating layer.

The technical purposes of the present disclosure are not limited to the technical purposes as mentioned above, and other technical purposes as not mentioned may be clearly understood by those skilled in the art from descriptions as set forth below.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is an example block diagram for illustrating a semiconductor memory device according to some embodiments;

FIG. 2 is a schematic layout diagram for illustrating a semiconductor memory device according to some embodiments;

FIG. 3 is a diagram for illustrating a semiconductor memory device according to some embodiments, and is a cross-sectional view taken along a line I-I′ of FIG. 2;

FIG. 4 is an enlarged view of an A1 area of FIG. 3;

FIG. 5 is a diagram for illustrating a semiconductor memory device according to some embodiments, and is a diagram corresponding to FIG. 4;

FIG. 6 is a diagram for illustrating a semiconductor memory device according to some embodiments, and is a diagram corresponding to FIG. 4;

FIG. 7 is a diagram for illustrating a semiconductor memory device according to some embodiments, and is a diagram corresponding to FIG. 4;

FIG. 8 is a diagram for illustrating a semiconductor memory device according to some embodiments, and is a diagram corresponding to FIG. 4;

FIG. 9 is another example cross-sectional view for illustrating a semiconductor memory device according to some embodiments;

FIG. 10 is an enlarged view of an A2 area of FIG. 9;

FIG. 11 is a diagram for illustrating a semiconductor memory device according to some embodiments, and is a diagram corresponding to FIG. 10;

FIG. 12 is a diagram for illustrating a semiconductor memory device according to some embodiments, and is a diagram corresponding to FIG. 10;

FIG. 13 is another example cross-sectional view for illustrating a semiconductor memory device according to some embodiments;

FIG. 14 is an enlarged view of an A3 area of FIG. 13;

FIG. 15 is another example cross-sectional view for illustrating a semiconductor memory device according to some embodiments;

FIG. 16 is an enlarged view of an A4 area of FIG. 15;

FIG. 17 is another example cross-sectional view for illustrating a semiconductor memory device according to some embodiments;

FIG. 18 is an enlarged view of an area A5 of FIG. 17;

FIG. 19 is another example cross-sectional view for illustrating a semiconductor memory device according to some embodiments;

FIG. 20 is another example cross-sectional view for illustrating a semiconductor memory device according to some embodiments;

FIGS. 21 to 28 are diagrams of intermediate structures corresponding to intermediate steps of a method for manufacturing a semiconductor memory device according to some embodiments;

FIGS. 29 to 33 are other diagrams of intermediate structures corresponding to intermediate steps of a method for manufacturing a semiconductor memory device according to some embodiments;

FIGS. 34 to 35 are other diagrams of intermediate structures corresponding to intermediate steps of a method for manufacturing a semiconductor memory device according to some embodiments;

FIGS. 36 to 37 are other diagrams of intermediate structures corresponding to intermediate steps of a method for manufacturing a semiconductor memory device according to some embodiments;

FIGS. 38 to 45 are other diagrams of intermediate structures corresponding to intermediate steps of a method for manufacturing a semiconductor memory device according to some embodiments;

FIGS. 46 to 51 are other diagrams of intermediate structures corresponding to intermediate steps of a method for manufacturing a semiconductor memory device according to some embodiments;

FIGS. 52 to 54 are other diagrams of intermediate structures corresponding to intermediate steps of a method for manufacturing a semiconductor memory device according to some embodiments;

FIGS. 55 to 61 are other diagrams of intermediate structures corresponding to intermediate steps of a method for manufacturing a semiconductor memory device according to some embodiments;

FIG. 62 is an example block diagram for illustrating an electronic system according to some embodiments;

FIG. 63 is an example perspective view for illustrating an electronic system according to some embodiments; and

FIG. 64 is a schematic cross-sectional view cut along a line II-II′ of FIG. 63.

### DETAILED DESCRIPTIONS

Hereinafter, embodiments of the present disclosure will be described as follows with reference to the accompanying drawings.

Items described in the singular herein may be provided in plural, as can be seen, for example, in the drawings. Thus, the description of a single item that is provided in plural should be understood to be applicable to the remaining plurality of items unless context indicates otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as “same,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

Spatially relative terms, such as “lower,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed herein in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

The semiconductor memory device may be semiconductor chip (i.e., a semiconductor device singulated from (e.g., cut from) a wafer).

As used herein the terms “on”, “over”, “covering”, “stacked” or “overlapping” or forms thereof, are intended to mean that an element is over or aside another element. The elements may be touching or not. For example, there may be layers between layers that are “on” one another. An element “on” or “over” or “stacked” over or “covering” or “overlapping” another element need not cover an entire top surface of an element below to be considered “on” or “over” or “stacked” over or “covering” or “overlapping”. The terms are intended to encompass one element “on” or “over” or “stacked” over or “covering” or “overlapping” all, or any part of, an element below it.

As used herein, the words “surround”, “surrounding” and “surrounded” are intended to mean that an element is outside the other element. The elements may be touching or not. The surrounding element may or may not completely surround an inner element.

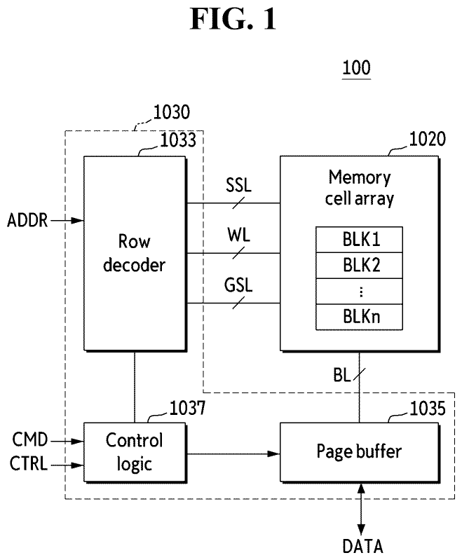

FIG. 1 is an example block diagram for illustrating a semiconductor memory device according to some embodiments.

Referring to FIG. 1, a semiconductor memory device 100 according to some embodiments includes a memory cell array 1020 and a peripheral circuit 1030.

The memory cell array 1020 may include a plurality of memory cell blocks BLK1 to BLKn. Each of the memory cell blocks BLK1 to BLKn may include a plurality of memory cells. The memory cell array 1020 may be connected to the peripheral circuit 1030 via a bit line BL, a word line WL, at least one string select line SSL, and at least one ground select line GSL. Specifically, the memory cell blocks BLK1 to BLKn may be connected to a row decoder 1033 via the word line WL, the string select line SSL, and the ground select line GSL. Furthermore, the memory cell blocks BLK1 to BLKn may be connected to a page buffer 1035 via the bit line BL.

The peripheral circuit 1030 may receive an address ADDR, a command CMD, and a control signal CTRL from an external source to the semiconductor memory device 100, and may transmit and receive data DATA to and from an external device to the semiconductor memory device 100. The peripheral circuit 1030 may include a control logic 1037, the row decoder 1033, and the page buffer 1035. Although not shown, the peripheral circuit 1030 may further include various sub-circuits such as an input/output circuit, a voltage generation circuit that generates various voltages required for the operation of the semiconductor memory device 100, and an error correction circuit for correcting errors in data DATA read out from the memory cell array 1020.

The control logic 1037 may be connected to the row decoder 1033, the input/output circuit, and the voltage generation circuit. The control logic 1037 may control overall operations of the semiconductor memory device 100. The control logic 1037 may generate various internal control signals used within the semiconductor memory device 100 in response to the control signal CTRL. For example, the control logic 1037 may adjust a voltage level provided to each of the word line WL and the bit line BL when performing a memory operation such as a program operation or an erase operation.

The row decoder 1033 may select at least one of a plurality of memory cell blocks BLK1 to BLKn in response to the address ADDR, and may select at least one word line WL, at least one string select line SSL, and at least one ground select line GSL of the selected memory cell blocks BLK1 to BLKn. Furthermore, the row decoder 1033 may transmit a voltage for performing a memory operation to the word line WL of the selected memory cell blocks BLK1 to BLKn.

The page buffer 1035 may be connected to the memory cell array 1020 via the bit line BL. The page buffer 1035 may operate as a writer driver or a sense amplifier. Specifically, when a program operation is performed, the page buffer 1035 may operate as a writer driver to apply a voltage corresponding to the data DATA to be stored in the memory cell array 1020 to the bit line BL. When a read operation is performed, the page buffer 1035 may operate as a sense amplifier to sense the data DATA stored in the memory cell array 1020.

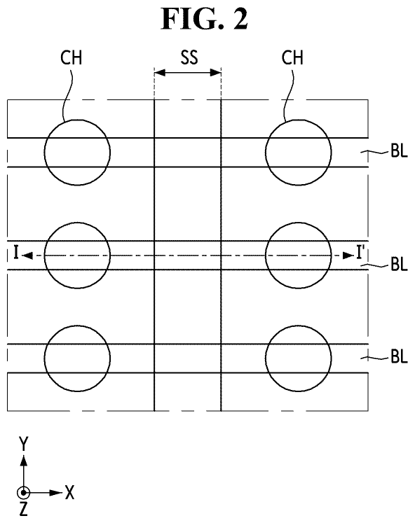

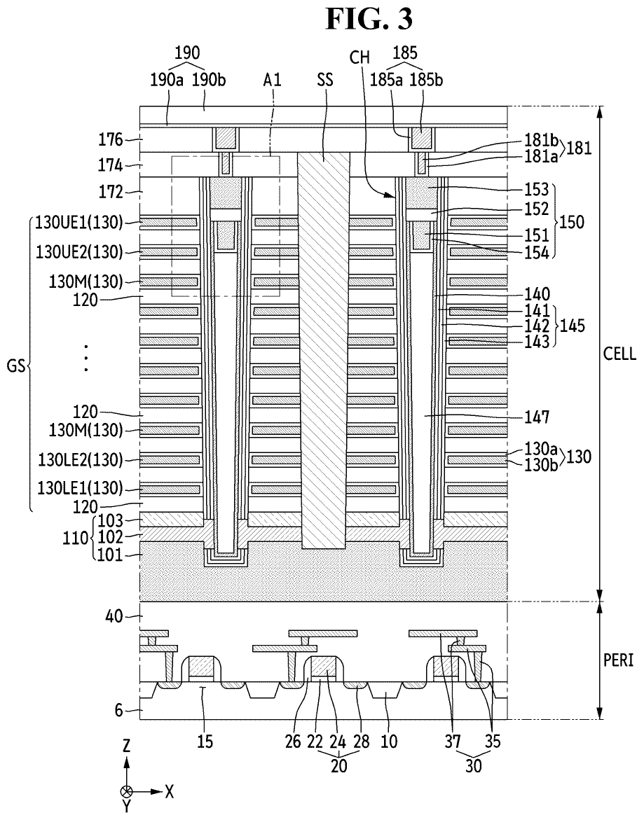

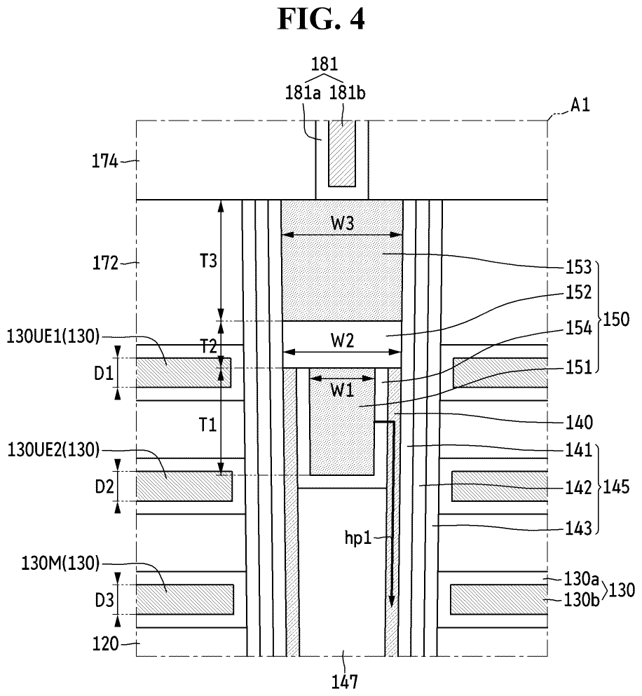

FIG. 2 is a schematic layout diagram for illustrating a semiconductor memory device according to some embodiments. FIG. 3 is a diagram for illustrating a semiconductor memory device according to some embodiments, and is a cross-sectional view taken along a line I-I′ of FIG. 2. FIG. 4 is an enlarged view of an A1 area of FIG. 3.

Referring to FIGS. 2 to 4, the semiconductor memory device according to some embodiments may include a memory cell structure CELL and a peripheral circuit structure PERI.

The peripheral circuit structure PERI may include a semiconductor substrate 6, circuit elements 20 disposed on the semiconductor substrate 6, a lower wiring structure 30 electrically connected to the circuit elements 20, and a lower capping layer 40. The circuit elements 20 may be circuit elements for an operation of a cell array of a NAND flash memory element.

An upper surface of the semiconductor substrate 6 may extend in each of a first direction X and a second direction Y intersecting the first direction X. In some embodiments, the first and second directions X and Y may mean horizontal directions intersecting each other perpendicularly. In some embodiments, a third direction Z may mean a height direction perpendicular to each of the first and second directions X and Y, or a vertical direction.

The memory cell structure CELL may include a pattern structure 110 on a peripheral circuit structure PERI, a stack structure GS including interlayer insulating layers 120 and gate electrodes 130 disposed on the pattern structure 110 and alternately stacked on top of each other, a channel structure CH extending through the stack structure GS in the third direction Z (e.g. a vertical direction), and an isolation structure SS.

The memory cell structure CELL may further include an upper capping layer 172, an upper insulating layer 174 and 176, contact plugs 181 and 185 connected to the channel structure CH, and a bit line 190 disposed on the contact plugs 181 and 185. The memory cell structure CELL may include an area where a cell array of a NAND flash memory element is disposed.

The semiconductor substrate 6 may include a semiconductor material, for example, a group IV semiconductor, a group III-V compound semiconductor, or a group II-VI compound semiconductor. For example, the group IV semiconductor may include silicon (Si), germanium (Ge), or silicon-germanium (SiGe). The semiconductor substrate 6 may be a single crystal silicon substrate. Element isolation layers 10 may be disposed within the semiconductor substrate 6, and source/drain areas 28 containing impurities may be disposed in a portion of an active area 15 defined between the element isolation layers 10.

Each of the circuit elements 20 may include a circuit gate dielectric layer 22, a circuit gate electrode 24, and the source/drain areas 28. The source/drain areas 28 may be respectively disposed on both opposing sides of the circuit gate electrode 24 and in the active area 15. A spacer layer 26 may be disposed on each of both opposing sides of the circuit gate electrode 24 so as to insulate the circuit gate electrode 24 and the source/drain area 28 from each other.

The circuit gate dielectric layer 22 may include silicon oxide, silicon nitride, silicon oxynitride, or a high-k material. The circuit gate electrode 24 may include at least one of titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). The circuit gate electrode 24 may include a semiconductor layer, for example, a doped polysilicon layer, or may include a material layer made of a metal-semiconductor compound. In some embodiments, the circuit gate electrode 24 may be composed of two or more layers.

The lower wiring structure 30 may be electrically connected to the circuit gate electrodes 24 and the source/drain areas 28 of the circuit elements 20. The lower wiring structure 30 may include lower contact plugs 35 having a cylindrical or truncated cone shape and lower wiring lines 37, at least one area of each thereof having a line shape. Some of the lower contact plugs 35 may be connected to the source/drain areas 28. Although not shown, the others of the lower contact plugs 35 may be connected to the gate electrodes 24. The lower contact plugs 35 may electrically connect the lower wiring lines 37 disposed at different vertical levels from the upper surface of the semiconductor substrate 6 to each other.

The lower wiring structure 30 may include a conductive material, for example, tungsten (W), copper (Cu), aluminum (Al), etc. Each of components thereof may further include a diffusion barrier including at least one of titanium (Ti), titanium nitride (TiN), tantalum (Ta), tantalum nitride (TaN), or tungsten nitride (WN). In some embodiments, the number of layers and arrangement pattern of the lower contact plugs 35 and the lower wiring lines 37 constituting the lower wiring structure 30 may be variously changed.

The lower capping layer 40 may cover the semiconductor substrate 6, the circuit elements 20, and the lower wiring structure 30. The lower capping layer 40 may be made of a material such as silicon oxide, silicon nitride, silicon oxynitride, or silicon oxycarbide. The lower capping layer 40 may be composed of a plurality of insulating layers. The lower capping layer 40 may include an etch stop layer made of silicon nitride.

The pattern structure 110 may include a lower pattern layer 101, a middle pattern layer 102 on the lower pattern layer 101, and an upper pattern layer 103 on the middle pattern layer 102. At least a portion of the pattern structure 110 may correspond to a common source line CSL.

The lower pattern layer 101 may include a semiconductor material such as polysilicon. The lower pattern layer 101 may include doped polysilicon. For example, the lower pattern layer 101 may include polysilicon having an N-conductivity type impurity. In this regard, the N-conductivity type impurity may include, for example, at least one of phosphorus (P), arsenic (As), or antimony (Sb) as N-type dopants.

In semiconductor technology, if a semiconductor contains both p-type and n-type impurities, the conductivity-type of the semiconductor will be determined by which type of impurity is in greater concentration. Therefore, if a semiconductor has both P-type and N-type impurities, the net conductivity type will be determined by the dominant impurity concentration.

The middle pattern layer 102 may extend along and on an upper surface of the lower pattern layer 101. The middle pattern layer 102 and the upper pattern layer 103 may function as a portion of the common source line of the semiconductor memory device. For example, the middle pattern layer 102 and the upper pattern layer 103 together with the lower pattern layer 101 may function as the common source line. The middle pattern layer 102 may extend through the channel insulating layer 145 so as to contact the channel layer 140. Each of the middle pattern layer 102 and the upper pattern layer 103 may include a semiconductor material such as polysilicon. For example, the middle pattern layer 102 may be a layer doped with an impurity of the same conductivity type as that of the lower pattern layer 101. The upper pattern layer 103 may be a doped layer or a layer containing an impurity diffused from the middle pattern layer 102. However, the material of the upper pattern layer 103 is not limited to a semiconductor material, and may include an insulating material.

The gate electrodes 130 may be stacked on the pattern structure 110 while being spaced apart from each other in the third direction Z. The gate electrodes 130 and the interlayer insulating layers 120 may be stacked to form the stack structure GS. The gate electrodes 130 may extend by different lengths while being disposed on at least one area of the pattern structure 110.

The gate electrodes 130 may include at least one lower gate electrode 130LE1 and 130LE2, at least one upper gate electrode 130UE1 and 130UE2, and middle gate electrodes 130M disposed between the at least one lower gate electrode 130LE1 and 130LE2 and the at least one upper gate electrode 130UE1 and 130UE2. The storage capacity of the semiconductor memory device may be determined based on the number of middle gate electrodes 130M constituting the memory cells.

The at least one lower gate electrodes 130LE1 and 130LE2 may include the first lower gate electrode 130LE1 and the second lower gate electrode 130LE2. For example, the first lower gate electrode 130LE1 may be a gate electrode of a lower erase control transistor, and the second lower gate electrode 130LE2 may be a gate electrode of a ground select transistor. However, embodiments of the present invention are not limited thereto.

The at least one upper gate electrodes 130UE1 and 130UE2 may include the first upper gate electrode 130UE1 and the second upper gate electrode 130UE2. For example, the first upper gate electrode 130UE1 may be a gate electrode of an upper erase control transistor, and the second upper gate electrode 130UE2 may be a gate electrode of a string select transistor. However, embodiments of the present invention are not limited thereto.

The first lower gate electrode 130LE1 may mean a “lowermost gate electrode” or a “lower erase control gate electrode”, and the second lower gate electrode 130LE2 may mean a “next-lowermost gate electrode” or a “ground select gate electrode”. The first upper gate electrode 130UE1 may mean an “uppermost gate electrode” or an “upper erase control gate electrode”, and the second upper gate electrode 130UE2 may mean a “next-uppermost gate electrode” or a “string select gate electrode”.

A thickness D1 of the first upper gate electrode 130UE1 in the third direction Z, a thickness D2 of the second upper gate electrode 130UE2 in the third direction Z, and a thickness D3 of the middle gate electrode 130M in the third direction Z may be substantially equal to each other. For example, each of the lower gate electrodes 130LE1 and 130LE2 and the upper gate electrodes 130UE1 and 130UE2 may have a thickness in the third direction Z of about 20 nm to about 30 nm or about 22 nm to about 28 nm. However, embodiments of the present invention are not limited thereto.

Alternatively, the thickness D1 in the third direction Z of the first upper gate electrode 130UE1 may be greater than each of the thickness D2 in the third direction Z of the second upper gate electrode 130UE2 and the thickness D3 in the third direction Z of the middle gate electrode 130M. For example, the thickness D1 in the third direction Z of the first upper gate electrode 130UE1 may be about 32 nm, the thickness D2 in the third direction Z of the second upper gate electrode 130UE2 may be about 30 nm, and the thickness D3 in the third direction Z of the middle gate electrode 130M may be about 26 nm. However, embodiments of the present invention are not limited thereto.

Each of the gate electrodes 130 may include a first gate layer 130a and a second gate layer 130b. The first gate layer 130a may include tungsten nitride (WN), tantalum nitride (TaN), titanium nitride (TiN), and/or a combination thereof. Furthermore, the second gate layer 130b may include a metal material, for example, tungsten (W). However, a configuration of each of the gate electrodes 130 is not limited thereto, and each of the gate electrodes 130 may be composed of three or more layers, and may include polysilicon or a metal silicide material. The gate electrode according to some embodiments may include the first gate layer 130a and the second gate layer 130b. For example, the corresponding gate electrode 130 constituting the upper erase control gate electrode 130UE1 may be understood to include the corresponding first gate layer 130a and second gate layer 130b.

Each of the interlayer insulating layers 120 may be disposed between adjacent gate electrodes 130. The interlayer insulating layers 120 and the gate electrodes 130 may be stacked alternatively on top of each other. For example each interlayer insulating layer of a plurality of interlayer insulating layers 120 and each gate electrode of a plurality of gate electrodes 130 may be stacked alternatively on top of each other. The interlayer insulating layers 120 may be arranged and be spaced apart from each other in the third direction Z. Each of the interlayer insulating layers 120 may include an insulating material such as silicon oxide, silicon nitride, or silicon oxynitride.

Each of the channel structures CH may constitute one memory cell string and may extend in the third direction Z perpendicular to the upper surface of the lower pattern layer 101. Each of the channel structures CH may extend through the stack structure GS in the third direction Z, and a lower end thereof may extend into a portion of a top portion of the lower pattern layer 101. The channel structures CH may be arranged and spaced apart from each other in row and column directions in a plan view while being disposed on the pattern structure 110. For example, the channel structures CH may be arranged in a lattice manner along a plane or may be arranged in a zigzag manner in one direction. Each of the channel structures CH may have a columnar shape having a side surface perpendicular to the upper surface of the lower pattern layer 101 or having an inclined side surface such that a width of the columnar shape becomes narrower as the columnar shape extends toward the lower pattern layer 101 according to an aspect ratio.

Each of the channel structures CH may include a channel layer 140, a channel insulating layer 145, a core insulating layer 147, and a channel pad 150. The channel insulating layer 145 may include a tunneling layer 141, an information storage layer 142, and a blocking layer 143 sequentially stacked from the channel layer 140.

The channel layer 140 may be formed in an annular shape surrounding the core insulating layer 147 as an inner core structure within the channel structure CH, and may be disposed on a side surface of the core insulating layer 147. The channel layer 140 may cover the side surface and a bottom surface of the core insulating layer 147. An outer side surface of a bottom portion of the channel layer 140 may contact the middle pattern layer 102. The channel layer 140 may extend through an area between the first upper gate electrode 130UE1 and the channel pad 150. The channel layer 140 may include a semiconductor material such as polysilicon. For example, the channel layer 140 may include polysilicon that is not doped with impurities. However, embodiments of the present invention are not limited thereto.

The channel insulating layer 145 may be disposed between the gate electrodes 130 and the channel layer 140. The channel insulating layer 145 may be disposed between the gate electrodes 130 and the channel layer 140 and extend upwardly beyond the first upper gate electrode 130UE1 and downwardly beyond the first lower gate electrode 130LE1.

The tunneling layer 141 may allow charges to tunnel into the information storage layer 142 therethrough. The tunneling layer 141 may include, for example, silicon oxide (SiO), or silicon oxynitride (SiON), or a combination thereof. The information storage layer 142 may be a charge trap layer. The information storage layer 142 may include, for example, silicon nitride (SiN). The blocking layer 143 may include silicon oxide (SiO), silicon oxynitride (SiON), or a high-k dielectric material, or a combination thereof.

The core insulating layer 147 may have a cylindrical shape extending in the third direction Z. An upper surface of the core insulating layer 147 may be in contact with the channel pad 150. The core insulating layer 147 may include silicon oxide or a low-k dielectric material.

The channel pad 150 may be disposed on the core insulating layer 147 and within the channel structure CH. The channel pad 150 may be disposed on an inner side surface of the channel layer 140 and may be in contact with the channel layer 140. At least a portion of the channel pad 150 may be surrounded with the first upper gate electrode 130UE1 in a horizontal direction parallel to the upper surface of the lower pattern layer 101. In other words, at least a portion of the channel pad 150 may overlap with the first upper gate electrode 130UE1 in the horizontal direction.

A level in the third direction Z of a bottom surface of the channel pad 150 may be located between a level in the third direction Z of a lower surface of the second upper gate electrode 130UE2 and a level in the third direction Z of an upper surface of the second upper gate electrode 130UE2. Alternatively, a level in the third direction Z of the bottom surface of the channel pad 150 may be substantially equal to a level in the third direction Z of the upper surface of the second upper gate electrode 130UE2. However, the technical idea of the present invention is not limited thereto.

The channel pad 150 may include a first pad layer 151 and a second pad layer 153.

The second pad layer 153 may be disposed on the first pad layer in the third direction Z. Accordingly, the first and second pad layers 151 and 153 may overlap each other in the vertical direction. As the first and second pad layers 151 and 153 are stacked in the third direction Z, a side surface of the first pad layer 151 may not be in contact with the second pad layer 153.

Because the channel structure CH has a shape in which the width becomes narrower as the channel structure extends toward the lower pattern layer 101, a horizontal first width W1 of the first pad layer 151 may be smaller than a horizontal second width W3 of the second pad layer 153.

The channel layer 140 may be disposed on a side surface of the first pad layer 151. The channel layer 140 may surround the side surface of the first pad layer 151. However, a second polysilicon layer 154 as described later may be interposed between the first pad layer 151 and the channel layer 140, such that the channel layer 140 may not directly contact the side surface of the first pad layer 151.

The channel insulating layer 145 may be disposed on the outermost side surface of the second pad layer 153. The channel insulating layer 145 may surround the outermost side surface of the second pad layer 153. The outermost side surface of the second pad layer 153 may contact the tunneling layer 141 of the channel insulating layer 145.

The first pad layer 151 may include a material of the first conductivity type. The second pad layer 153 may include a material of a second conductivity type that is different from the first conductivity type. For example, the first pad layer 151 may include polysilicon doped with P-type impurities, and the second pad layer 153 may include polysilicon doped with N-type impurities.

The channel pad 150 may further include a first polysilicon layer 152 between the first and second pad layers 151 and 153. An upper surface of the first pad layer 151 and a lower surface of the second pad layer 153 may be in contact with the first polysilicon layer 152. The first pad layer 151, the first polysilicon layer 152, and the second pad layer 153 may be stacked in the third direction Z.

For example, a thickness T2 in the third direction Z of the first polysilicon layer 152 may be smaller than each of a thickness T1 in the third direction Z of the first pad layer 151 and a thickness T3 in the third direction Z of the second pad layer 153. For example, a horizontal width W2 of the first polysilicon layer 152 may be larger than the first horizontal width W1 of the first pad layer 151 and may be smaller than the second horizontal width W3 of the second pad layer 153.

The first polysilicon layer 152 may include polysilicon that is not doped with impurities. In some embodiments, the first polysilicon layer 152 may be referred to as a first semiconductor material layer. For example, the first polysilicon layer 152 may be deposited or epitaxially grown on the first pad layer 151.

The channel pad 150 may further include the second polysilicon layer 154 between the channel layer 140 and the first pad layer 151. The channel layer 140 may surround a side surface of the second polysilicon layer 154. The second polysilicon layer 154 may be disposed on the core insulating layer 147. The side surface and a lower surface of the second polysilicon layer 154 may be in contact with the channel layer 140 and the core insulating layer 147, respectively. The second polysilicon layer 154 may be conformally formed along a portion of the side surface of the channel layer 140 and the upper surface of the core insulating layer 147.

The second polysilicon layer 154 may surround the side surface and the lower surface of the first pad layer 151. The side surface and the lower surface of the first pad layer 151 may be in contact with the second polysilicon layer 154.

A level in the third direction Z of the upper surface of the second polysilicon layer 154 may be equal to a level in the third direction Z of the upper surface of the channel layer 140. The upper surface of the second polysilicon layer 154 may be in contact with the lower surface of the first polysilicon layer 152. The upper surface of the channel layer 140 may be in contact with the lower surface of the first polysilicon layer 152.

The second polysilicon layer 154 may include polysilicon that is not doped with impurities. In some embodiments, the second polysilicon layer 154 may be referred to as a second semiconductor material layer.

In the semiconductor memory device in accordance with some embodiments, a pad layer 151 including a P-type impurity may be formed in bulk and may be disposed in the channel pad 150 connected to the bit line. Accordingly, during an erase operation, a voltage may be applied to the pad layer 151 including the P-type impurity, so that holes may be directly injected into the channel layer 140. The holes may be injected into the channel layer 140 of the channel structure CH to allow electrons trapped in the information storage layer 142 to escape to the channel layer 140.

In other words, during the erase operation of the semiconductor memory device, a voltage may be applied to the first and second pad layers 151 and 153, so that holes may be injected into the channel layer 140. The holes may be injected into the channel layer 140 via a first path hp1 passing through the first pad layer 151 and the second polysilicon layer 154.

The isolation structure SS may extend through the stack structure GS in the third direction Z and extend along the second direction Y in a plan view. The isolation structure SS may extend in the second direction Y so as to isolate the gate electrodes 130 of the stack structure GS from each other in the first direction X.

Based on the upper surface of the lower pattern layer 101, a level in the third direction Z of an upper surface of the isolation structure SS may be higher than a level in the third direction Z of the upper surface of the channel structure CH. The isolation structure SS may extend through an entirety of the stacked gate electrodes 130 so as to contact the pattern structure 110. The isolation structure SS may have a shape having a width that decreases as the isolation structure extends toward the lower pattern layer 101 due to a high aspect ratio thereof.

The isolation structure SS may include an insulating material such as silicon oxide or silicon nitride. Alternatively, the isolation structure SS may include a conductive layer in contact with the insulating spacer and the lower pattern layer 101.

The upper capping layer 172 may cover a top of the stack structure GS and a side surface of a top portion of the channel structures CH. An upper surface of the upper capping layer 172 may be substantially coplanar with the upper surface of the channel structure CH. The upper capping layer 172 may include silicon oxide, silicon nitride, silicon oxynitride, or silicon oxycarbide.

The upper insulating layers 174 and 176 may be disposed on the upper capping layer 172. The upper insulating layers 174 and 176 may include the first upper insulating layer 174 and the second upper insulating layer 176. An upper surface of the first upper insulating layer 174 may be substantially coplanar with the upper surface of the isolation structure SS. The second upper insulating layer 176 may be disposed on the first upper insulating layer 174 and the isolation structure SS. The upper insulating layers 174 and 176 may include silicon oxide, silicon nitride, silicon oxynitride, or silicon oxycarbide.

The contact plugs 181 and 185 may be connected to the channel structures CH. The contact plugs 181 and 185 may include the first contact plug 181 and the second contact plug 185. The first contact plug 181 may be in contact with the channel pad 150. The contact plugs 181 and 185 may electrically connect the channel structure CH and the bit line 190 to each other. Each of the contact plugs 181 and 185 may include each of barrier layers 181a and 185a and each of conductive layers 181b and 185b. For example, the barrier layer 181a may surround a lower surface and a side surface of the conductive layer 181b. Each of the barrier layers 181a and 185a may include at least one of, for example, titanium (Ti), titanium nitride (TiN), tantalum (Ta), tantalum nitride (TaN), tungsten nitride (WN), or tungsten carbon nitride (WCN). Each of the conductive layers 181b and 185b may include a conductive material, for example, a metal material such as tungsten (W), copper (Cu), or aluminum (Al).

The bit line 190 may extend in the first direction X and may be disposed on the stack structure GS and the channel structures CH. The bit line 190 may be electrically connected to the channel layer 140. The bit line 190 may include a barrier layer 190a and a conductive layer 190b. The barrier layer 190a may include at least one of, for example, titanium (Ti), titanium nitride (TiN), tantalum (Ta), tantalum nitride (TaN), tungsten nitride (WN), or tungsten carbon nitride (WCN). The conductive layer 190b may include a conductive material, for example, a metal material such as tungsten (W), copper (Cu), or aluminum (Al).

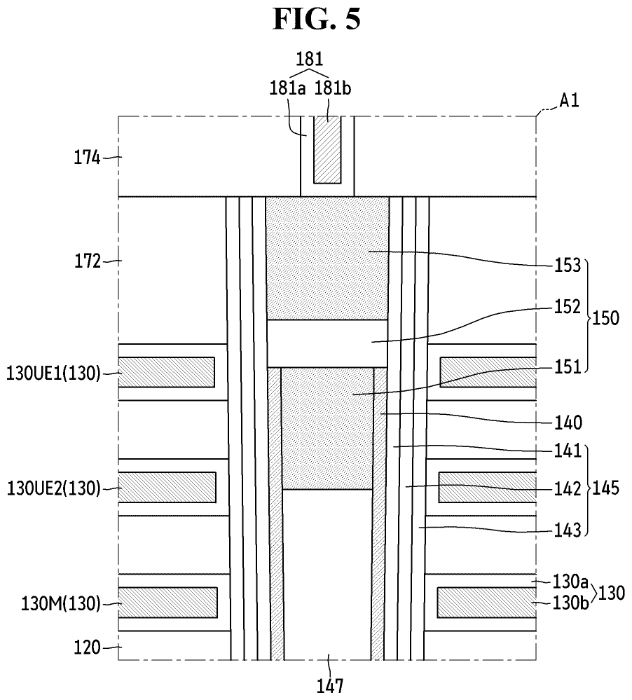

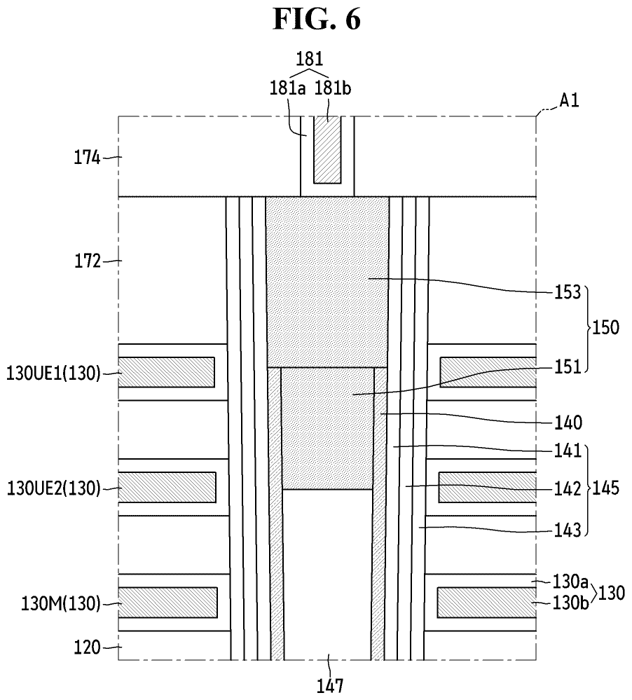

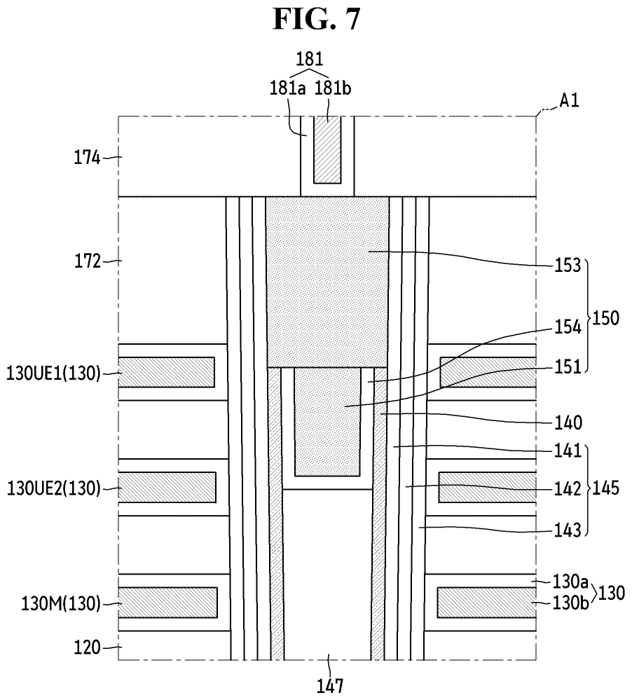

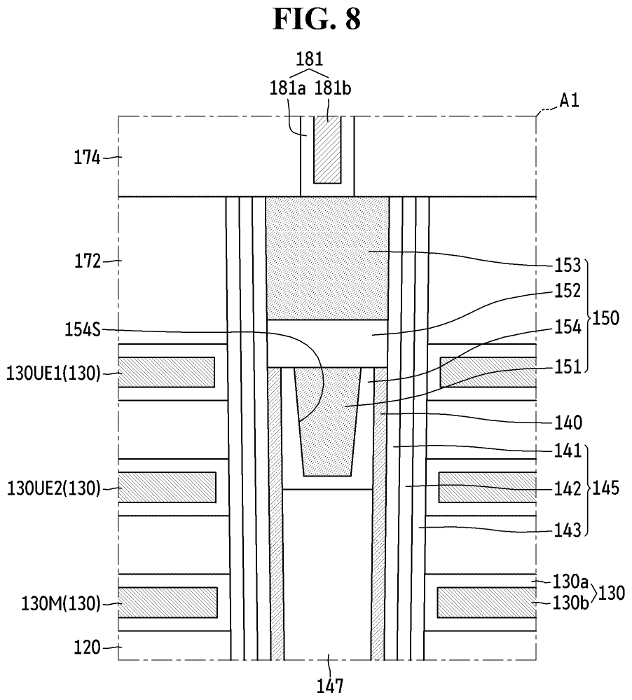

FIG. 5 is a diagram for illustrating a semiconductor memory device according to some embodiments, and is a diagram corresponding to FIG. 4. FIG. 6 is a diagram for illustrating a semiconductor memory device according to some embodiments, and is a diagram corresponding to FIG. 4. FIG. 7 is a diagram for illustrating a semiconductor memory device according to some embodiments, and is a diagram corresponding to FIG. 4. FIG. 8 is a diagram for illustrating a semiconductor memory device according to some embodiments, and is a diagram corresponding to FIG. 4. For convenience of description, contents duplicate with those as described above with reference to FIGS. 1 to 4 are briefly described or descriptions thereof are omitted.

Referring to FIG. 5, the semiconductor memory device according to some embodiments may include the first polysilicon layer 152 and may not include the second polysilicon layer 154. The side surface of the channel layer 140 may be in contact with the side surface of the first pad layer 151. The lower surface of the first pad layer 151 and the upper surface of the core insulating layer 147 may be in contact with each other.

Referring to FIG. 6, the semiconductor memory device according to some embodiments may not include both the first polysilicon layer 152 and the second polysilicon layer 154. The first and second pad layers 151 and 153 may be in contact with each other.

The upper surface of the first pad layer 151 and the lower surface of the second pad layer 153 may be in contact with each other.

Referring to FIG. 7, the semiconductor memory device according to some embodiments may include the second polysilicon layer 154 and may not include the first polysilicon layer 152. The upper surface of the second polysilicon layer 154 may be in contact with the lower surface of the second pad layer 153. The upper surface of the channel layer 140 may be in contact with the lower surface of the second pad layer 153.

Referring to FIG. 8, at least one sidewall of the second polysilicon layer 154 of the semiconductor memory device according to some embodiments may have an inclined shape. Specifically, an inner sidewall 154S of the second polysilicon layer 154 in contact with the first pad layer 151 may have an inclined shape. A width of the second polysilicon layer 154 may increase as the second polysilicon layer 154 extends toward the upper surface of the semiconductor substrate 6. A first width of the first pad layer 151 within the second polysilicon layer 154 may decrease as the first pad layer 151 extends toward the semiconductor substrate 6.

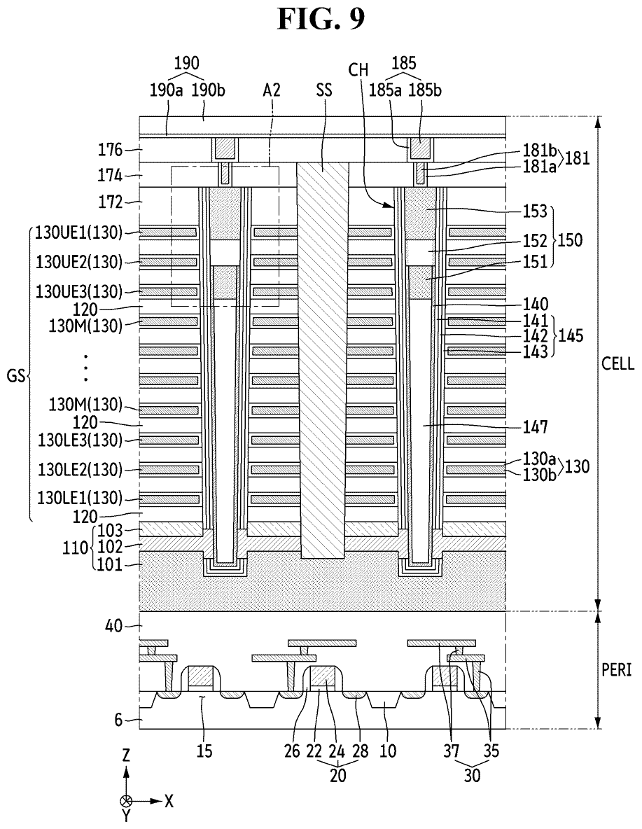

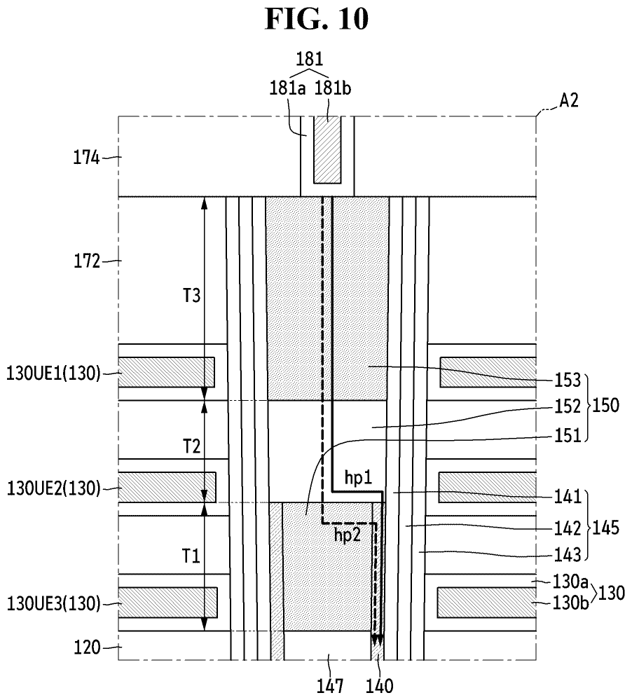

FIG. 9 is another example cross-sectional view for illustrating a semiconductor memory device according to some embodiments. FIG. 10 is an enlarged view of an A2 area of FIG. 9. For the convenience of description, components the same as those described above with reference to FIGS. 1 to 8 are briefly described or descriptions thereof are omitted.

Referring to FIGS. 9 and 10, the second pad layer 153 of the semiconductor memory device according to some embodiments may at least partially overlap the uppermost gate electrode 130UE1 adjacent to the bit line 190 among the gate electrodes 130. For example, the second pad layer 153 may at least partially overlap the first upper gate electrode 130UE1 in the horizontal direction.

The at least one upper gate electrodes 130UE1, 130UE2, and/or 130UE3 may include the first upper gate electrode 130UE1, the second upper gate electrode 130UE2, and/or the third upper gate electrode 130UE3. For example, the first to third upper gate electrodes 130UE1, 130UE2, and 130UE3 may be gate electrodes of an erase control transistor, and the middle gate electrode 130M disposed thereunder may be a gate electrode of a string select transistor. However, embodiments of the present invention are not limited thereto.

A level in the third direction Z of the bottom surface of the channel pad 150 may be substantially equal to a level in the third direction Z of a lower surface of the third upper gate electrode 130UE3, or may be lower than a level in the third direction Z of the lower surface of the third upper gate electrode 130UE3. However, the technical idea of the present invention is not limited thereto.

For example, the thickness T3 of the second pad layer 153 may be greater than each of the thickness T1 of the first pad layer 151 and the thickness T2 of the first polysilicon layer 152. However, embodiments of the present invention are not limited thereto.

The first pad layer 151 may include polysilicon doped with N-type impurities, and the second pad layer 153 may include polysilicon doped with P-type impurities.

When an erase operation of the semiconductor memory device is performed, a voltage may be applied to the second pad layer 153 to inject holes into the channel layer 140. The holes may be injected into the channel layer 140 via the first path hp1 passing through the second pad layer 153 and the first polysilicon layer 152. Alternatively, the holes may be injected into the channel layer 140 via a second path hp2 passing through the second pad layer 153, the first polysilicon layer 152, and the first pad layer 151.

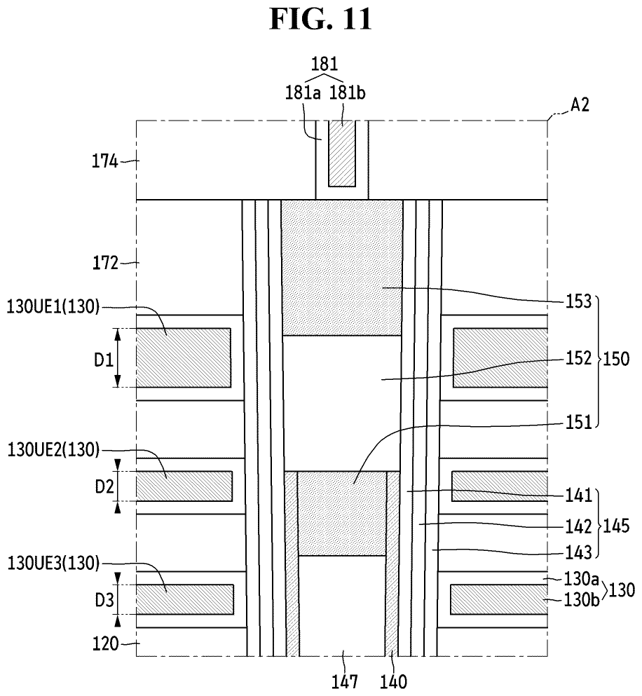

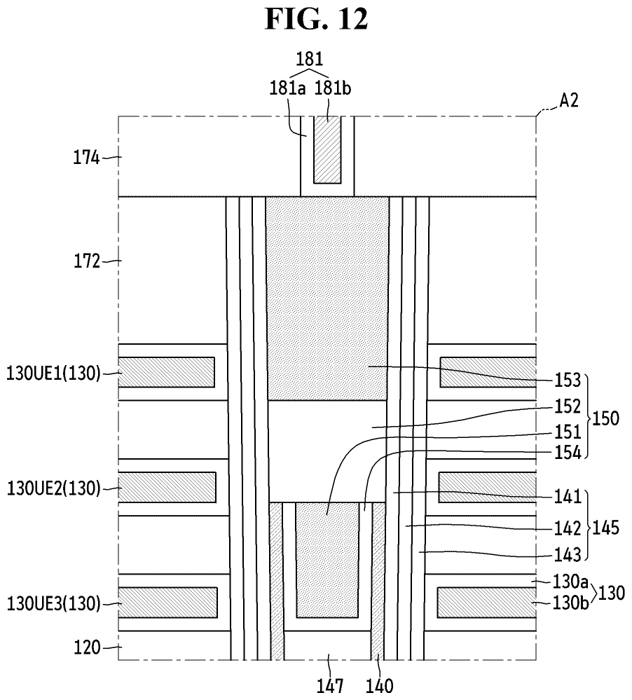

FIG. 11 is a diagram for illustrating a semiconductor memory device according to some embodiments, and is a diagram corresponding to FIG. 10. FIG. 12 is a diagram for illustrating a semiconductor memory device according to some embodiments, and is a diagram corresponding to FIG. 10. For convenience of description, components the same as those described above with reference to FIGS. 1 to 10 are briefly described or descriptions thereof are omitted.

Referring to FIG. 11, the thickness D1 of the first upper gate electrode 130UE1 in the third direction Z may be greater than each of the thickness D2 of the second upper gate electrode 130UE2 in the third direction Z and the thickness D3 of the third upper gate electrode 130UE3 in the third direction Z. For example, the thickness D1 in the third direction Z of the first upper gate electrode 130UE1 may be about 32 nm, the thickness D2 in the third direction Z of the second upper gate electrode 130UE2 may be about 30 nm, and the thickness D3 in the third direction Z of the middle gate electrode 130M may be about 26 nm. However, embodiments of the present invention are not limited thereto.

A level in the third direction Z of the bottom surface of the channel pad 150 may be located between a level in the third direction Z of the lower surface of the second upper gate electrode 130UE2 and a level in the third direction Z of the upper surface of the third upper gate electrode 130UE3, or may be substantially equal to a level in the third direction Z of the lower surface of the second upper gate electrode 130UE2. However, the technical idea of the present invention is not limited thereto.

Referring to FIG. 12, the semiconductor memory device according to some embodiments may further include the second polysilicon layer 154, compared to the semiconductor memory device of FIG. 10.

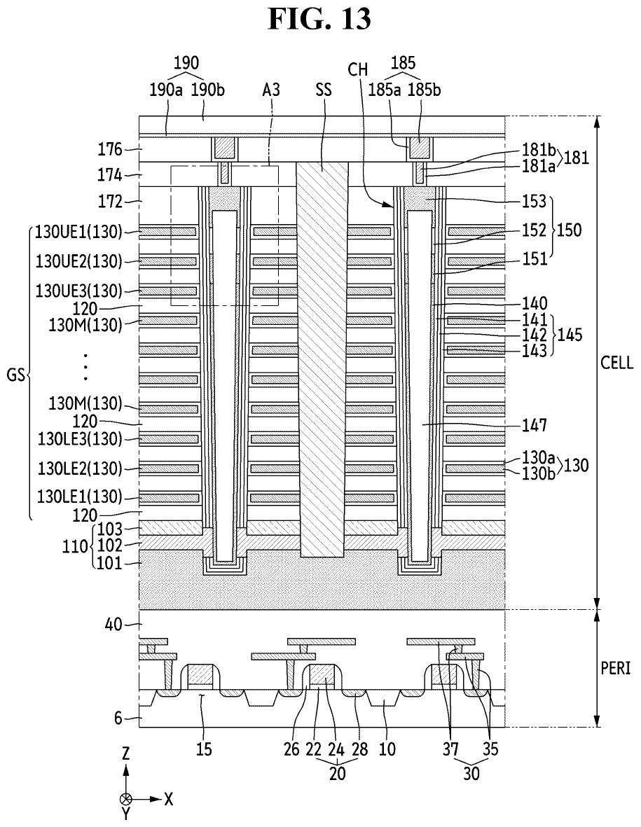

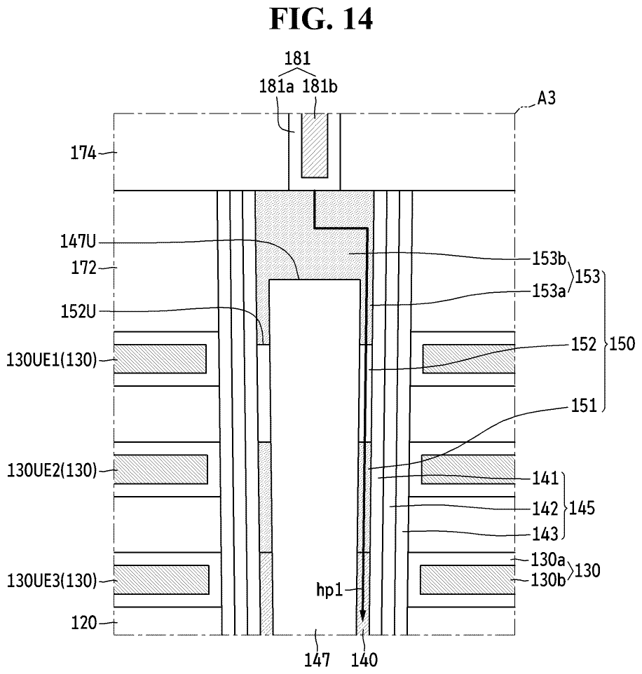

FIG. 13 is another example cross-sectional view for illustrating a semiconductor memory device according to some embodiments. FIG. 14 is an enlarged view of an A3 area of FIG. 13. For convenience of description, components the same as those described above with reference to FIGS. 9 to 12 are briefly described or descriptions thereof are omitted.

Referring to FIGS. 13 and 14, the semiconductor memory device according to some embodiments may include a combination of the first pad layer 151 and the first polysilicon layer 152 of a line type that extends in an elongate manner in the third direction Z.

The channel layer 140 may extend in the third direction Z while being disposed between the core insulating layer 147 and the channel insulating layer 145. The first pad layer 151 may be disposed on top of the channel layer 140 and between the core insulating layer 147 and the channel insulating layer 145. The first polysilicon layer 152 may be disposed on top of the first pad layer 151 and between the core insulating layer 147 and the channel insulating layer 145.

The upper surface of the channel layer 140 may be in contact with the lower surface of the first pad layer 151. The channel layer 140 may not be in contact with the side surface of the first pad layer 151.

In the third direction Z, an upper surface 147U of the core insulating layer 147 may be located at a higher level than that of the upper surface 152U of the first polysilicon layer 152.

The first pad layer 151, the first polysilicon layer 152, and the second pad layer 153 may be in contact with each of both opposing side surfaces of the core insulating layer 147. The second pad layer 153 may surround a portion of a side wall and the upper surface of the core insulating layer 147. The second width of the second pad layer 153 may be larger than the width of the core insulating layer 147.

The second pad layer 153 may include a first area 153a disposed on top of the first polysilicon layer 152 and contacting the side surface of the core insulating layer 147 and the upper surface of the first polysilicon layer 152, and a second area 153b disposed on top of the first area 153a and contacting the upper surface of the core insulating layer 147 and the side surface of the channel insulating layer 145. In the third direction Z, the first area 153a may be located at a lower level than that of the upper surface 147U of the core insulating layer.

The maximum thickness in the third direction Z of the second pad layer 153 may be greater than each of the thickness in the third direction Z of the first pad layer 151 and the thickness in the third direction Z of the first polysilicon layer 152.

The first pad layer 151 may include polysilicon doped with N-type impurities, and the second pad layer 153 may include polysilicon doped with P-type impurities.

When an erase operation of the semiconductor memory device is performed, a voltage may be applied to the second pad layer 153 to inject holes into the channel layer 140. The holes may be injected into the channel layer 140 via the first path hp1 passing through the second pad layer 153, the first polysilicon layer 152, and the first pad layer 151.

The semiconductor memory device of FIGS. 13 and 14 may include the first pad layer 151 and the first polysilicon layer 152 that are narrower than those of the semiconductor memory device of FIGS. 9 to 12. Accordingly, a depletion area may be reduced, and the operation of the semiconductor memory device may be controlled more effectively.

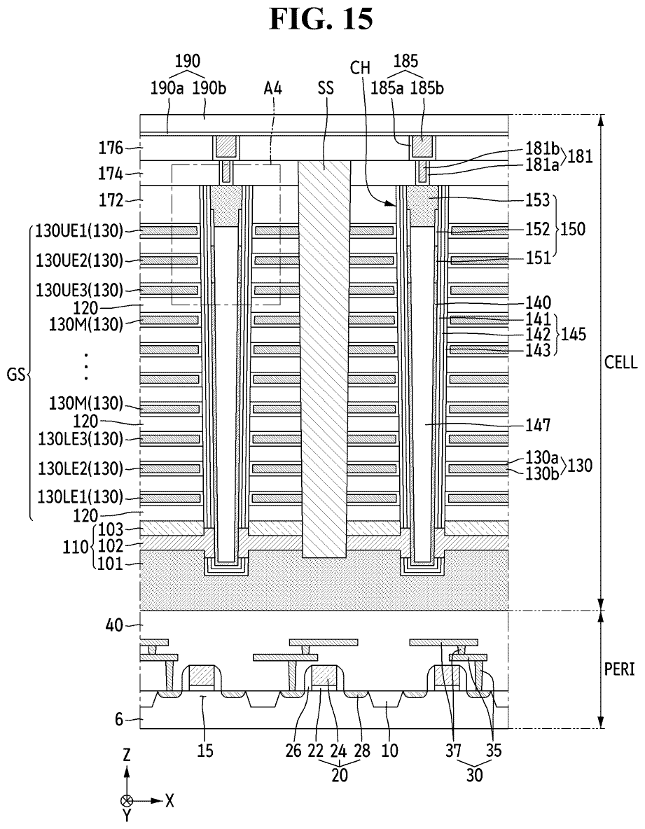

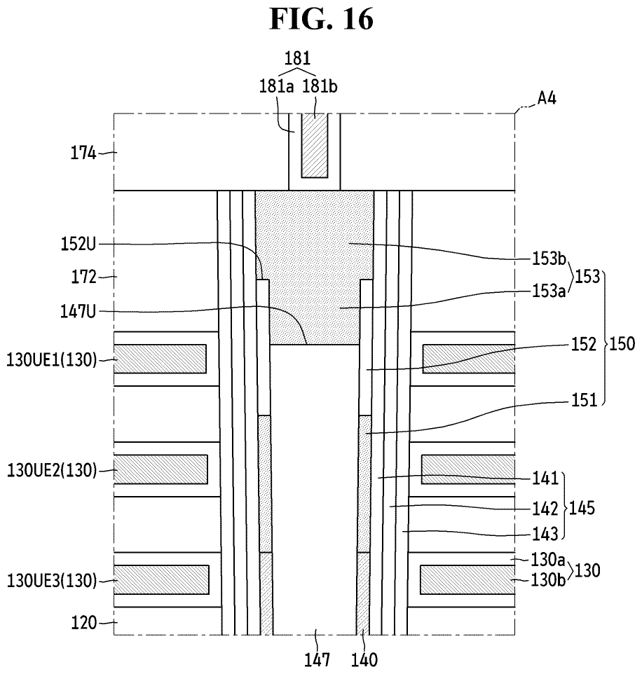

FIG. 15 is another example cross-sectional view for illustrating a semiconductor memory device according to some embodiments. FIG. 16 is an enlarged view of an A4 area of FIG. 15. For convenience of description, components the same as those described above with reference to FIGS. 13 and 14 are briefly described or descriptions thereof are omitted.

Referring to FIGS. 15 and 16, the second pad layer 153 of the semiconductor memory device according to some embodiments may be T-shaped.

The channel layer 140 may extend in the third direction Z while being disposed between the core insulating layer 147 and the channel insulating layer 145. The first pad layer 151 may be disposed on top of the channel layer 140 and between the core insulating layer 147 and the channel insulating layer 145. The first polysilicon layer 152 may be disposed on top of the first pad layer 151 and between the core insulating layer 147 and the channel insulating layer 145.

In the third direction Z, the upper surface 147U of the core insulating layer 147 may be positioned at a lower level than that of the upper surface 152U of the first polysilicon layer 152.

The second pad layer 153 may be positioned on a portion of an inner side surface and the upper surface of the first polysilicon layer 152. The second pad layer 153 may include the first area 153a that contacts the upper surface of the core insulating layer 147 and the side surface of the first polysilicon layer 152, and the second area 153b disposed on top of the first area 153a and contacting the upper surface of the first polysilicon layer 152 and the side surface of the channel insulating layer 145. In the third direction Z, the first area 153a may be positioned on the upper surface 147U of the core insulating layer.

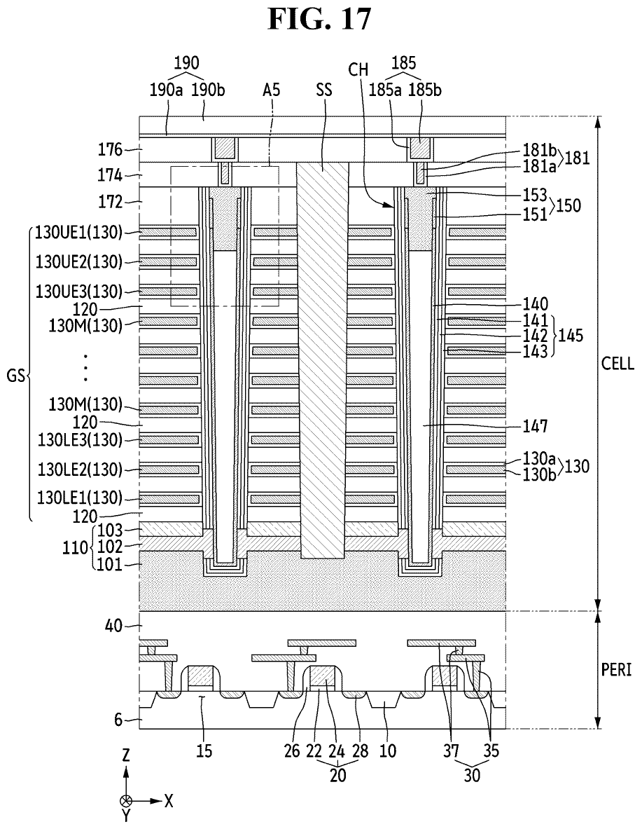

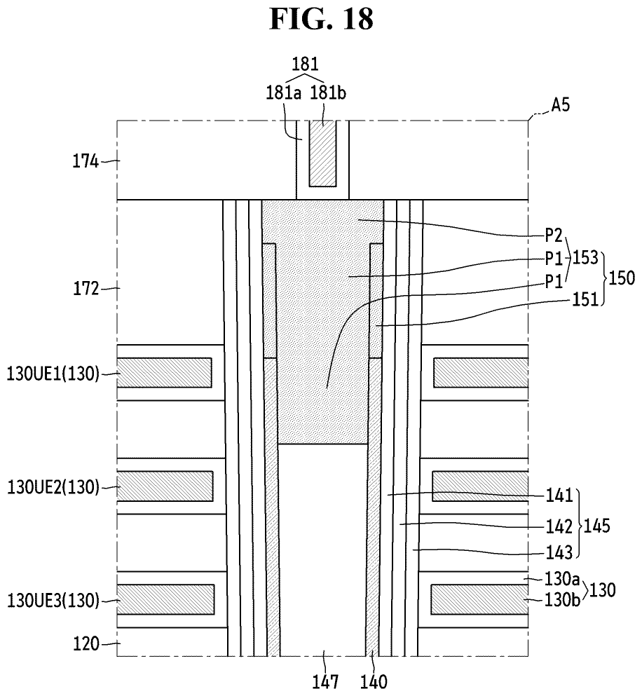

FIG. 17 is another example cross-sectional view for illustrating a semiconductor memory device according to some embodiments. FIG. 18 is an enlarged view of an area A5 of FIG. 17. For convenience of description, components the same as those a described above with reference to FIGS. 1 to 16 are briefly described or descriptions thereof are omitted.

Referring to FIGS. 17 and 18, the second pad layer 153 may include a first area P1 that contacts the side surface of the channel layer 140, a second area P2 that is disposed on top of the first area P1 and contacts the side surface of the first pad layer 151, and a third area P3 that is disposed on top of the second area P2 and contacts the side surface of the channel insulating layer 145. A width of the third area P3 may be larger than widths of each of the first area P1 and the second area P2.

The first pad layer 151 may include a first side surface and a second side surface that face each other. The first side surface may contact the channel insulating layer 145, and the second side surface may contact the second pad layer 153.

The first pad layer 151 may include an upper surface and a lower surface that face each other. The upper surface may contact the second pad layer 153, and the lower surface may contact the channel layer 140.

In one example, although not specifically shown, the first pad layer 151 may further extend so as to at least partially overlap the second upper gate electrode 130UE2.

The first pad layer 151 may include polysilicon doped with P-type impurities, and the second pad layer 153 may include polysilicon doped with N-type impurities.

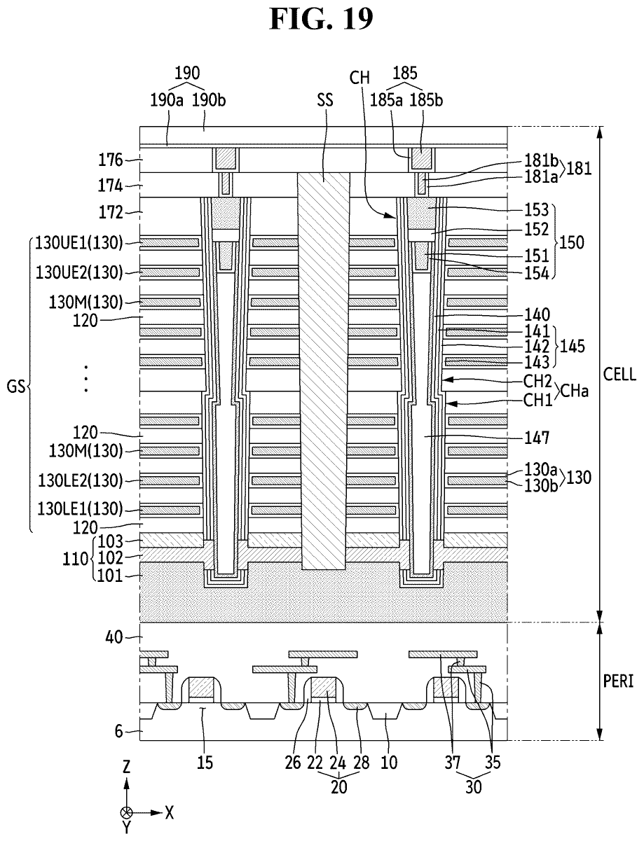

FIG. 19 is another example cross-sectional view for illustrating a semiconductor memory device according to some embodiments. For convenience of description, components the same as those described above with reference to FIGS. 1 to 18 are briefly described or descriptions thereof are omitted.

Referring to FIG. 19, the stack structure GS of the memory cell structure CELL may include a lower stack structure and an upper stack structure disposed on top of the lower stack structure. Each of channel structures CHa may include a lower channel structure CH1 extending through the lower stack structure and an upper channel structure CH2 extending through the upper stack structure. The channel layer 140 of the first channel structure CH1 and the channel layer 140 of the second channel structure CH2 may be connected to each other. In the connection area, each of the channel insulating layer 145 and the channel layer 140 may be bent. For example, the side surface of the channel layer 140 may include a bent portion due to a width difference in the above-mentioned connection area, and an inclination of the side surface thereof may change. The present embodiment illustrates an example in which the stack structure is a double-stack structure in which the number of stacks is two. The present disclosure may propose an example in which the stack structure is a multi-stack structure in which the number of the stacks is at least three.

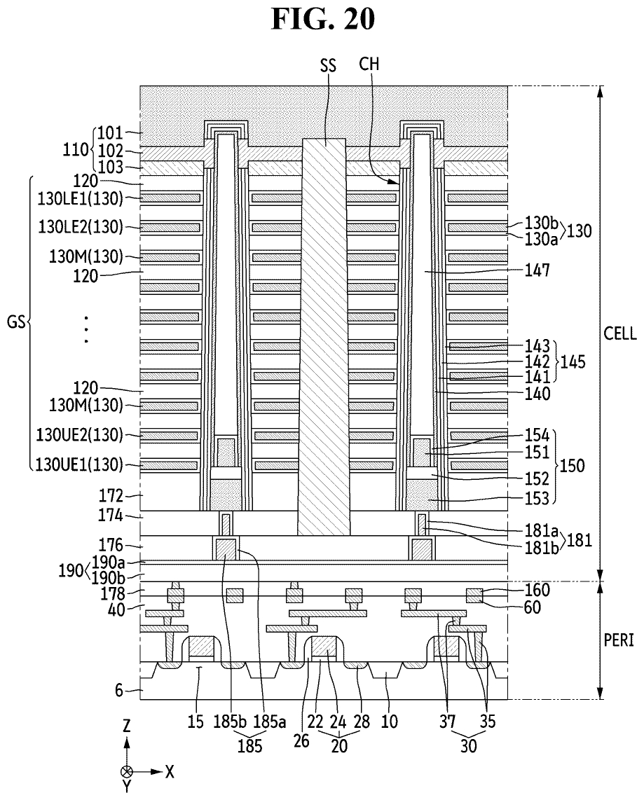

FIG. 20 is another example cross-sectional view for illustrating a semiconductor memory device according to some embodiments. For convenience of description, components the same as those described above with reference to FIGS. 1 to 19 are briefly described or descriptions thereof are omitted.

Referring to FIG. 20, a peripheral circuit structure PERI and a memory cell structure CELL may be bonded to each other via a bonding structure. The memory cell structure CELL may further include an upper bonding pad 160 and a lower bonding pad 60. The memory cell structure CELL may further include a third upper insulating layer 178. The upper bonding pad 160 may be electrically connected to the bit line 190 via a separate via, and the lower bonding pad 60 may be electrically connected to the circuit elements 20 via a separate via.

Each of the lower bonding pad 60 and the upper bonding pad 160 may include, for example, tungsten (W), aluminum (Al), copper (Cu), tungsten nitride (WN), tantalum nitride (TaN), titanium nitride (TiN), or a combination thereof.

The lower bonding pad 60 and the upper bonding pad 160 may function as bonding layers for bonding the peripheral circuit structure PERI and the memory cell structure CELL to each other. Furthermore, the lower bonding pad 60 and the upper bonding pad 160 may provide an electrical connection path between the peripheral circuit structure PERI and the memory cell structure CELL. The lower bonding pad 60 and the upper bonding pad 160 may be bonded to each other in a copper (Cu)-copper (Cu) bonding manner.

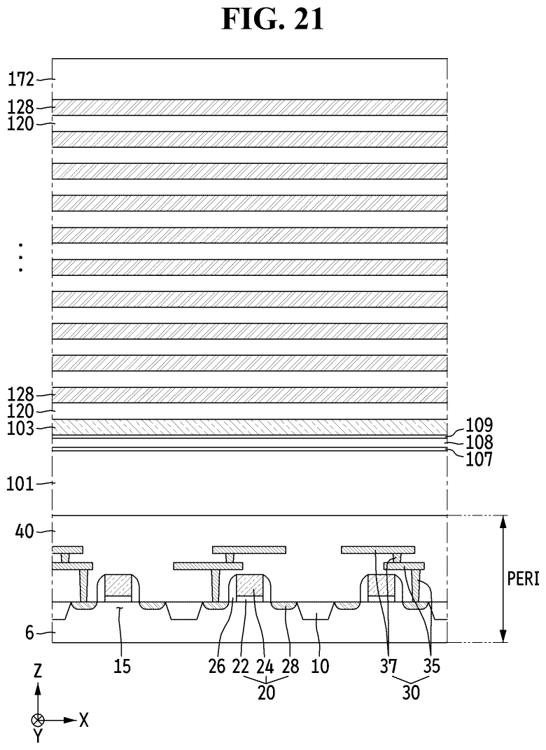

FIGS. 21 to 28 are diagrams of intermediate structures corresponding to intermediate steps of a method for manufacturing a semiconductor memory device according to some embodiments. For convenience of description, components the same as those described above with reference to FIGS. 1 to 4 are briefly described or descriptions thereof are omitted. For reference, FIGS. 21 to 28 are diagrams of intermediate structures corresponding to intermediate steps of a method for manufacturing the semiconductor memory device as illustrated in FIG. 4.

Referring to FIG. 21, the peripheral circuit structure PERI including the circuit elements 20, the lower wiring structure 30, and the lower capping layer 40 may be formed on the semiconductor substrate 6. The lower pattern layer 101, horizontal sacrificial layers 107, 108, and 109, and the upper pattern layer 103 may be formed on the peripheral circuit structure PERI. The interlayer insulating layers 120 and sacrificial layers 128 may be alternately stacked on top of each other while being disposed on the upper pattern layer 103.

First, the element isolation layers 10 may be formed in the semiconductor substrate 6, and the circuit gate dielectric layers 22 and the circuit gate electrodes 24 may be sequentially formed on the active area 15. The element isolation layers 10 may be formed, for example, in a shallow trench isolation (STI) process. The circuit gate dielectric layer 22 may be made of silicon oxide, and the circuit gate electrode 24 may be made of at least one of polysilicon or a metal silicide layer. However, embodiments of the present invention are not limited thereto. Thereafter, the spacer layer 26 may be formed on each of both opposing sidewalls of each of the circuit gate dielectric layer 22 and the circuit gate electrode 24, and the source/drain areas 28 may be formed in the portion of the active area 15. According to embodiments, the spacer layer 26 may be composed of a plurality of layers. The source/drain areas 28 may be formed in an ion implantation process.

The lower contact plugs 35 and the lower wiring lines 37 of the lower wiring structure 30 may be formed by forming a portion of the lower capping layer 40, etching a portion thereof to remove the same, and filling the removed area with a conductive material, or by depositing a conductive material, patterning the deposited material, and filling an area removed by patterning the material with a portion of the lower capping layer 40.

The lower capping layer 40 may be composed of a plurality of insulating layers. Some insulating layers of the lower capping layer 40 may be formed in each of the steps forming the lower wiring structure 30, and the other insulating layers thereof may be formed on the uppermost lower wiring line 37, such that ultimately the lower capping layer 40 composed of the plurality of insulating layers may be formed to cover the circuit elements 20 and the lower wiring structure 30.

The lower pattern layer 101 may be formed on the peripheral circuit structure PERI, and may include a semiconductor material such as polysilicon, for example.

The horizontal sacrificial layers 107, 108, and 109 may be sequentially stacked on the lower pattern layer 101. The horizontal sacrificial layers 107, 108, and 109 may include the first layer 107, the second layer 108, and the third layer 109, which may be replaced with the middle pattern layer (102 of FIG. 3) formed in a subsequent process. Each of the first and third layers 107 and 109 may be made of the same material as that of the interlayer insulating layers 120, and may be made of, for example, silicon oxide. The second layer 108 may be made of the same material as that of the sacrificial layers 128, and may be made of, for example, silicon nitride.

The upper pattern layer 103 may be formed on the horizontal sacrificial layers 107, 108, and 109. Although not shown, the upper pattern layer 103 may include an area in which the horizontal sacrificial layers 107, 108, and 109 are bent along the side surface of the patterned area so as to contact the lower pattern layer 102. The upper pattern layer 103 may include a semiconductor material, for example, polysilicon.

The sacrificial layers 128 may be partially replaced with the gate electrodes (130 in FIG. 3) in a subsequent process. The sacrificial layers 128 may be made of a material different from the interlayer insulating layers 120, and may be made of a material having an etching selectivity with respect to the interlayer insulating layers 120 under a specific etching condition. For example, the interlayer insulating layer 120 may include at least one of silicon oxide or silicon nitride. The sacrificial layers 128 may include at least one of silicon, silicon oxide, silicon carbide, or silicon nitride, and may be made of a material different from the material of the interlayer insulating layer 120. In embodiments, all of thicknesses of the interlayer insulating layers 120 may not be equal to each other. The thicknesses of the interlayer insulating layers 120, the thicknesses of the sacrificial layers 128, the number of films constituting the interlayer insulating layers 120 and the number of films constituting the sacrificial layers 128 may vary to be different from those as illustrated. The upper capping layer 172 may be further formed on the upper sacrificial layer 128. The upper capping layer 172 may include silicon nitride.

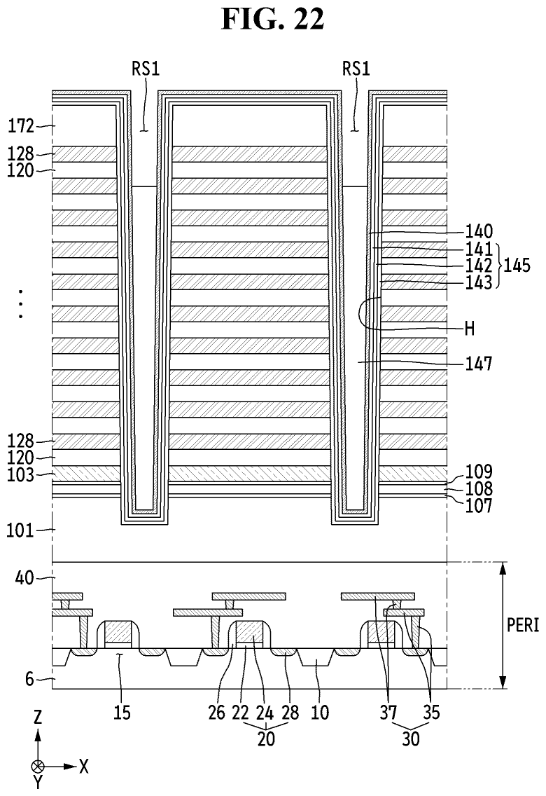

Referring to FIG. 22, a channel hole H extending through the stack structure of the interlayer insulating layers 120 and the sacrificial layers 128 may be formed, and the channel insulating layer 145, the channel layer 140, and the core insulating layer 147 may be formed within the channel hole H. A portion of the core insulating layer 147 may be downwardly removed from a top thereof to form a first recess RS1 exposing a portion of a side surface of the channel layer 140. For example, forming the first recess RS1 by removing the portion of the core insulating layer 147 may be performed in a wet etching or dry etching process.

The channel hole H may be formed by anisotropically etching the stack structure of the interlayer insulating layers 120 and the sacrificial layers 128 in the third direction Z. The channel hole H may extend through the upper capping layer 172, the upper pattern layer 103, and the horizontal sacrificial layers 107, 108, and 109, and be recessed into the lower pattern layer 101.

The channel insulating layer 145 may be conformally formed within the channel hole H. Forming the channel insulating layer 145 may include sequentially forming the blocking layer 143, the information storage layer 142, and the tunneling layer 141 on a sidewall of the channel hole H. Afterwards, the channel layer 140 may be conformally formed on the channel insulating layer 145 and within the channel hole H, and the core insulating layer 147 may be formed to fill a remaining space of the channel hole H. A depth of the first recess RS1 may be determined in consideration of a level in the third direction Z of the bottom surface of the channel pad 150.

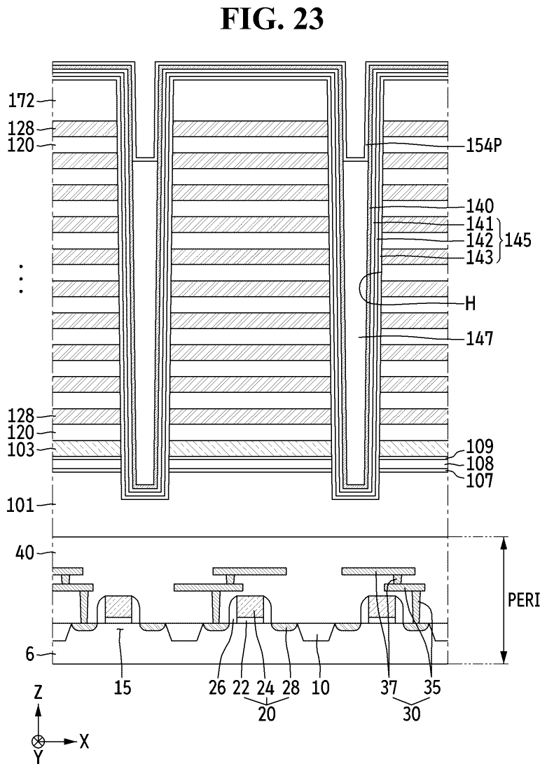

Referring to FIG. 23, a first pre-polysilicon layer 154P may be formed. The first pre-polysilicon layer 154P may be conformally formed to cover an inner side surface of the channel layer 140 and a bottom surface of the first recess RS1 as exposed by removing the portion of the core insulating layer 147. The first pre-polysilicon layer 154P may extend to be formed on a top surface of the upper capping layer 172. In a subsequent process, the first pre-polysilicon layer 154P may be partially removed by performing a planarization process thereon. The first pre-polysilicon layer 154P may be partially removed so as to remain only in the channel hole H to constitute the second polysilicon layer 154 of the channel pad 150 of FIG. 4. A shape and a thickness thereof may be variously changed depending on the etching process and the deposition process.

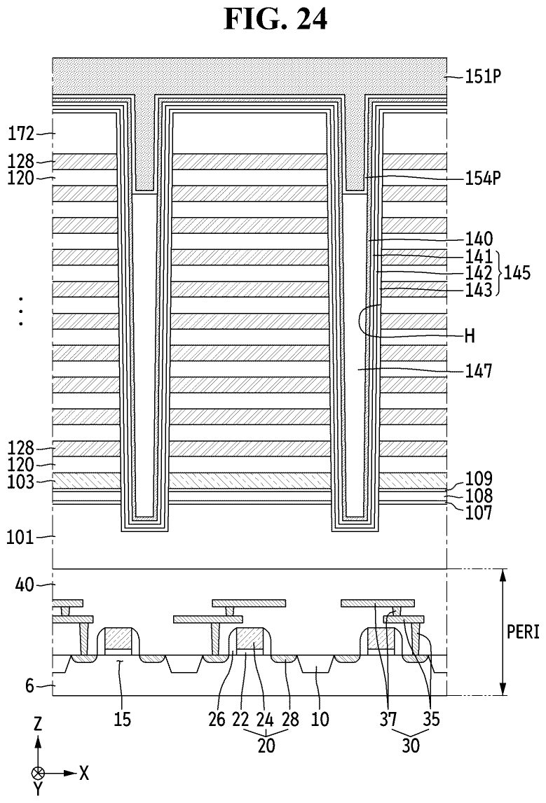

Referring to FIG. 24, a first pre-pad layer 151P may be formed on the first pre-polysilicon layer 154P. The first pre-pad layer 151P may be formed in a space of the first recess RS1 remaining after the first pre-polysilicon layer 154P has been formed therein. The first pre-pad layer 151P may be deposited on the first pre-polysilicon layer 154P so as to constitute the first pad layer 151 of the channel pad 150 of FIG. 4.

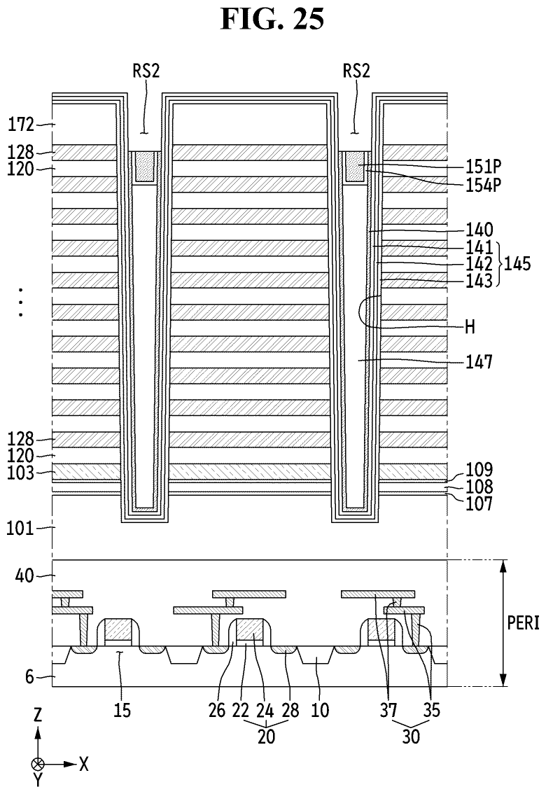

Referring to FIG. 25, a portion of the first pre-polysilicon layer 154P and a portion of the first pre-pad layer 151P may be removed from a top thereof to form a second recess RS2. The second recess RS2 may expose a portion of an inner side surface of the tunneling layer 141, an upper surface of the channel layer 140, an upper surface of the first pre-polysilicon layer 154P, and an upper surface of the first pre-pad layer 151P. For example, forming the second recess RS2 by removing the portion of each of the first pre-polysilicon layer 154P and the first pre-pad layer 151P may be performed in a wet etching process or a dry etching process.

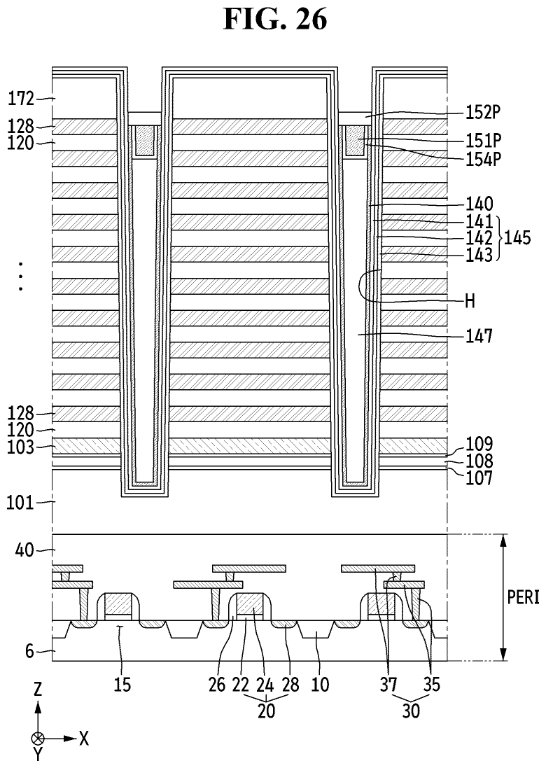

Referring to FIG. 26, a second pre-polysilicon layer 152P may be formed. The second pre-polysilicon layer 152P may be formed on the portion of the inner side surface of the tunneling layer 141 and a bottom surface of the second recess RS2. The second pre-polysilicon layer 152P may be formed on the portion of the inner side surface of the tunneling layer 141, the upper surface of the channel layer 140, the upper surface of the first pre-polysilicon layer 154P, and the upper surface of the first pre-pad layer 151P. The second pre-polysilicon layer 152P may be formed using a deposition process or an epitaxial growth process to constitute the first polysilicon layer 152 of the channel pad 150 of FIG. 4.

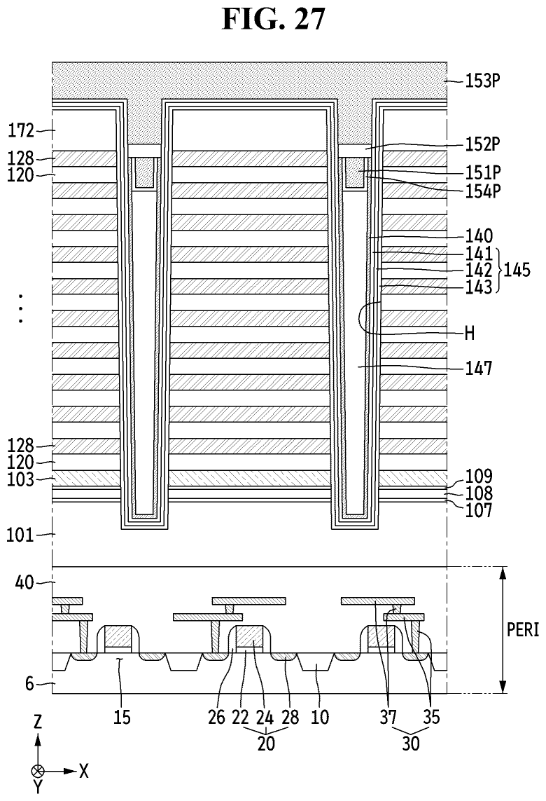

Referring to FIG. 27, a second pre-pad layer 153P may be formed on the second pre-polysilicon layer 152P. The second pre-pad layer 153P may be formed in a space of the second recess RS2 remaining after the second pre-polysilicon layer 152P has been formed therein. The second pre-pad layer 153P may be deposited on the second pre-polysilicon layer 152P to constitute the second pad layer 153 of the channel pad 150 of FIG. 4.

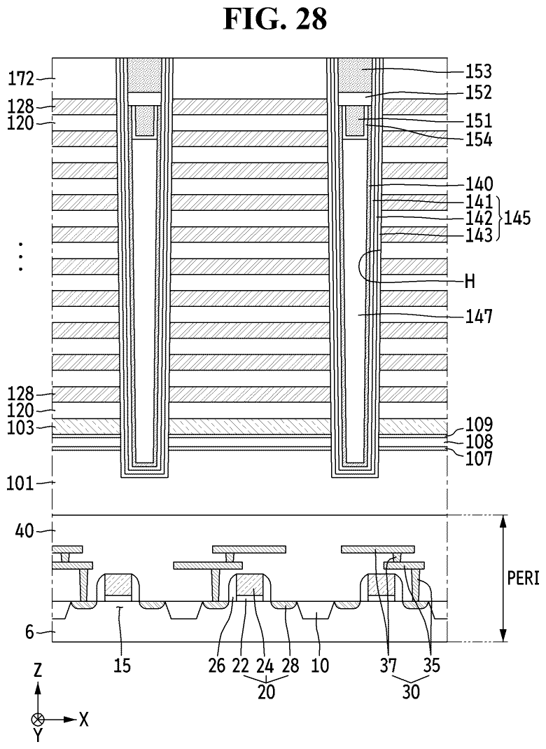

Referring to FIG. 28, a portion of the channel insulating layer 145 and a portion of the second pre-pad layer 153P disposed on top of the upper capping layer 172 may be removed. In this regard, a planarization process may be performed until an upper surface of the upper capping layer 172 is exposed. Accordingly, the upper surface of the second pad layer 153 and the upper surface of the upper capping layer 172 may be coplanar with each other. Accordingly, the second polysilicon layer 154, the first pad layer 151, the first polysilicon layer 152, and the second pad layer 153 of the channel pad 150 of FIG. 4 may be formed.

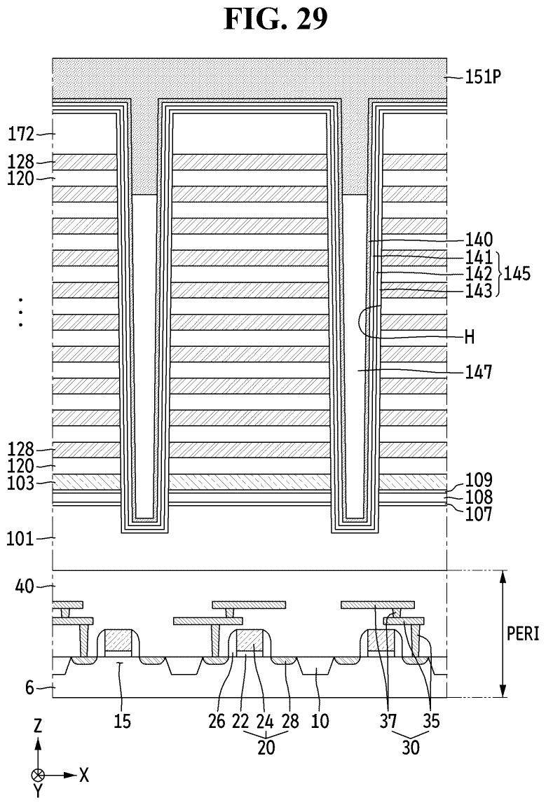

FIGS. 29 to 33 are other diagrams of intermediate structures corresponding to intermediate steps of an example method for manufacturing a semiconductor memory device according to some embodiments. For convenience of description, components the same as those described above with reference to FIGS. 21 to 28 are briefly described or descriptions thereof are omitted. For reference, FIGS. 29 to 33 are diagrams of intermediate structures corresponding to intermediate steps of a method for manufacturing a semiconductor memory device as illustrated in FIG. 5.

FIG. 29 is a diagram showing an example process after the first recess RS1 of FIG. 22 is formed.

Referring to FIG. 29, the first pre-pad layer 151P may be formed on the inner side surface of the channel layer 140 and the bottom surface of the first recess RS1. The first pre-pad layer 151P may be deposited on the core insulating layer 147 to constitute the first pad layer 151 of the channel pad 150 of FIG. 5.

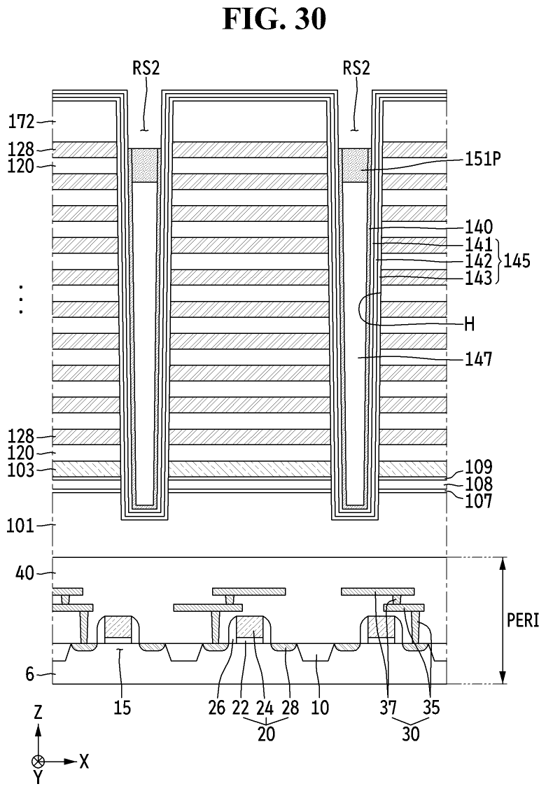

Referring to FIG. 30, a portion of each of the channel layer 140 and the first pre-pad layer 151P may be removed from a top thereof to form a second recess RS2. The second recess RS2 may expose a portion of an inner side surface of the tunneling layer 141, an upper surface of the channel layer 140, and an upper surface of the first pre-pad layer 151P. Removing the portion of each of the channel layer 140 and the first pre-pad layer 151P may be performed using, for example, a wet etching process or a dry etching process.

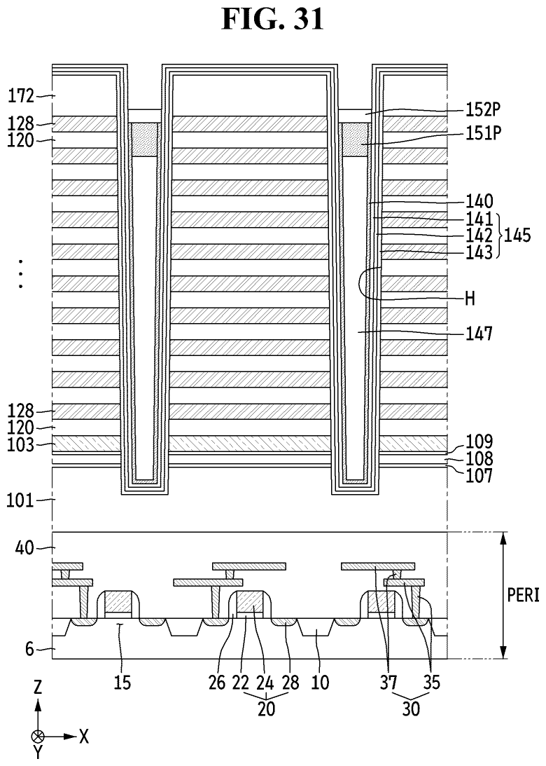

Referring to FIG. 31, the second pre-polysilicon layer 152P may be formed on the portion of the inner side surface of the tunneling layer 141 and a bottom surface of the second recess RS2. The second pre-polysilicon layer 152P may be formed on the portion of the inner side surface of the tunneling layer 141, the upper surface of the channel layer 140, and the upper surface of the first pre-pad layer 151P. The second pre-polysilicon layer 152P may be formed using a deposition process or an epitaxial growth process to constitute the first polysilicon layer 152 of the channel pad 150 of FIG. 5.

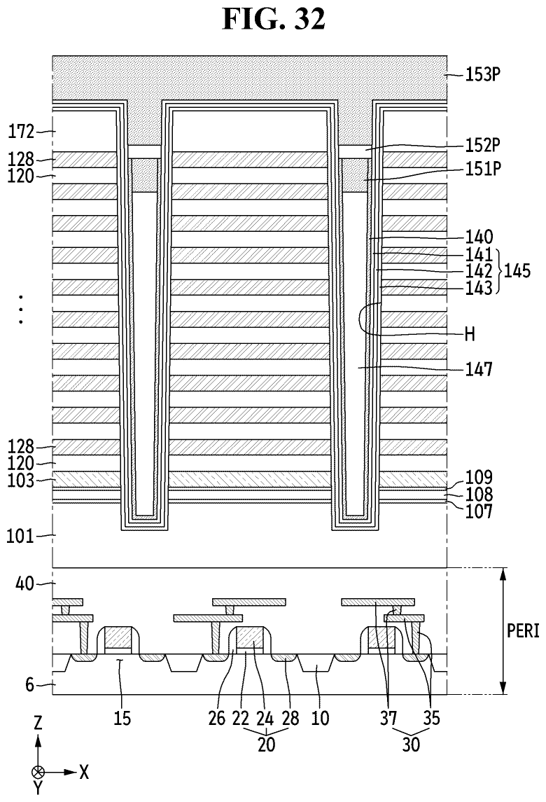

Referring to FIG. 32, the second pre-pad layer 153P may be formed on the second pre-polysilicon layer 152P. The second pre-pad layer 153P may be formed in a space of the second recess RS2 remaining after the second pre-polysilicon layer 152P has been formed therein. The second pre-pad layer 153P may be deposited on the second pre-polysilicon layer 152P to constitute the second pad layer 153 of the channel pad 150 of FIG. 5.

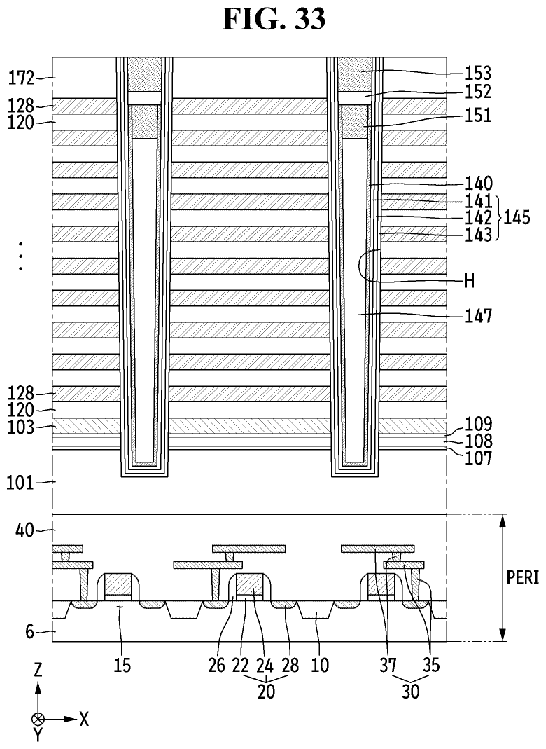

Referring to FIG. 33, a portion of each of the channel insulating layer 145 and the second pre-pad layer 153P disposed on top of the upper capping layer 172 may be removed. In this regard, a planarization process may be performed until the upper surface of the upper capping layer 172 is exposed. Accordingly, the upper surface of the second pad layer 153 and the upper surface of the upper capping layer 172 may be coplanar with each other. Accordingly, the first pad layer 151, the first polysilicon layer 152, and the second pad layer 153 of the channel pad 150 of FIG. 5 may be formed.

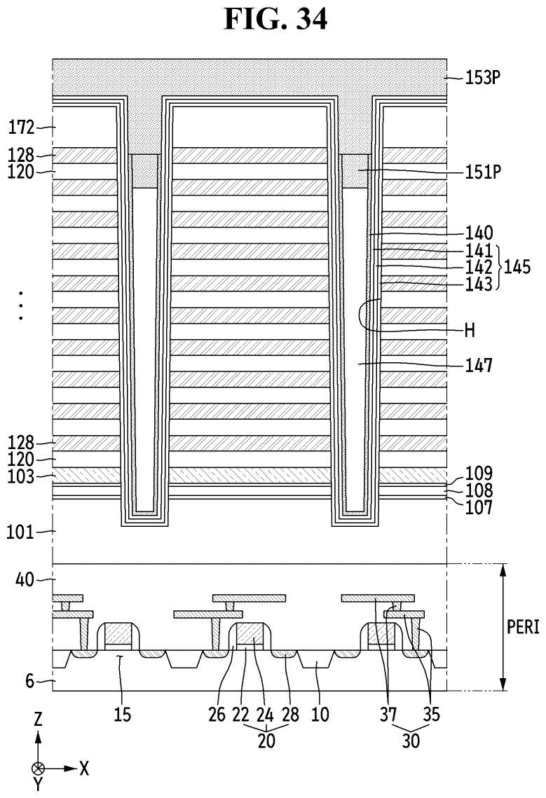

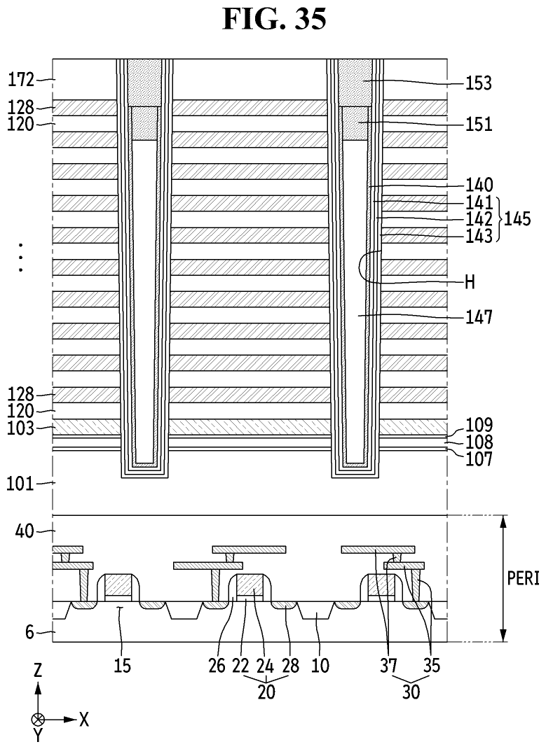

FIGS. 34 to 35 are other diagrams of intermediate structures corresponding to intermediate steps of a method for manufacturing a semiconductor memory device according to some embodiments. For convenience of description, contents components the same as those described above with reference to FIGS. 21 to 33 are briefly described or descriptions thereof are omitted. For reference, FIGS. 34 to 35 are diagrams of intermediate structures corresponding to intermediate steps of a method for manufacturing the semiconductor memory device as illustrated in FIG. 6.

FIG. 34 is a diagram showing a process after the second recess RS2 of FIG. 30 is formed.

Referring to FIG. 34, the second pre-pad layer 153P may be formed on the inner side surface of the tunneling layer 141 and the bottom surface of the second recess RS2. The second pre-pad layer 153P may be formed using a deposition process to constitute the second pad layer 153 of the channel pad 150 of FIG. 6.

Referring to FIG. 35, a portion of each of the channel insulating layer 145 and the second pre-pad layer 153P disposed on top of the upper capping layer 172 may be removed. For this purpose, a planarization process may be performed until the upper surface of the upper capping layer 172 is exposed. Accordingly, the upper surface of the second pad layer 153 and the upper surface of the upper capping layer 172 may be coplanar with each other. Accordingly, the first pad layer 151 and the second pad layer 153 of the channel pad 150 of FIG. 6 may be formed.

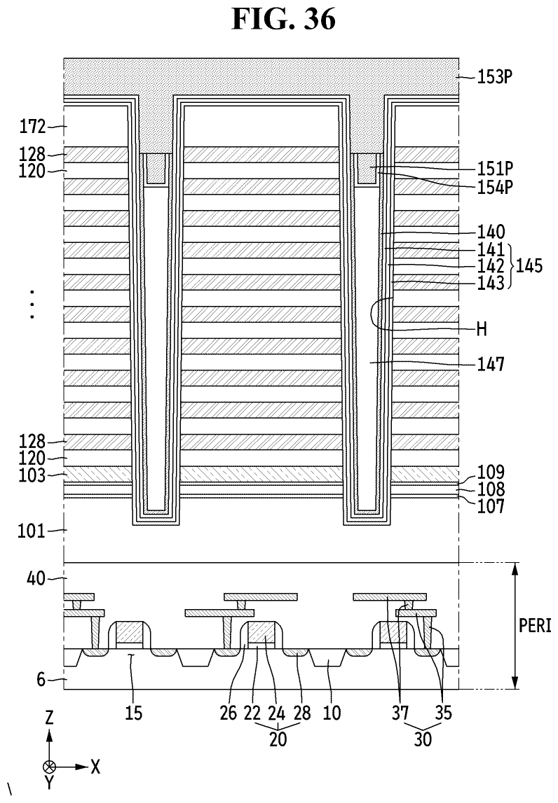

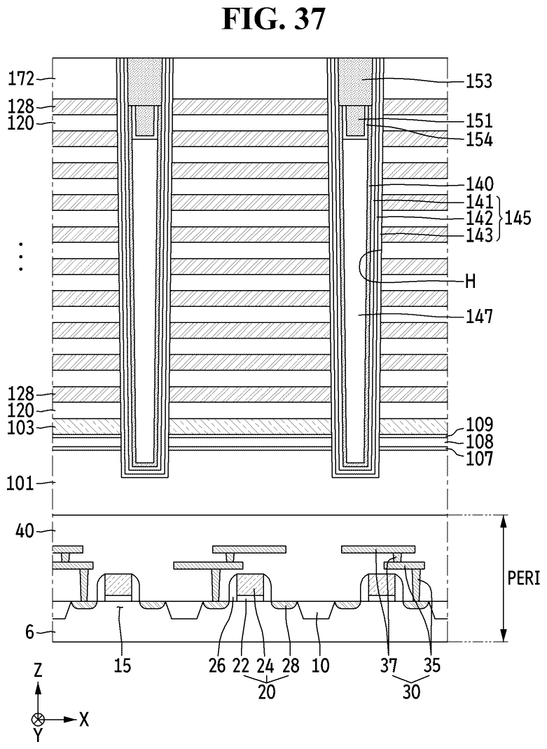

FIGS. 36 to 37 are other diagrams of example intermediate structures corresponding to intermediate steps of a method for manufacturing a semiconductor memory device according to some embodiments. For convenience of description, components the same as those described above with reference to FIGS. 21 to 35 are briefly described or descriptions thereof are omitted. For reference, FIGS. 36 to 37 are diagrams of intermediate structures corresponding to intermediate steps of a method for manufacturing a semiconductor memory device as illustrated in FIG. 7.

FIG. 36 is a diagram showing a process after the second recess RS2 of FIG. 25 is formed.

Referring to FIG. 36, the second pre-pad layer 153P may be formed on the portion of the inner side surface of the tunneling layer 141 and the bottom surface of the second recess RS2. The second pre-pad layer 153P may be formed on the portion of the inner side surface of the tunneling layer 141, the upper surface of the channel layer 140, the upper surface of the first pre-polysilicon layer 154P, and the upper surface of the first pre-pad layer 151P. The second pre-pad layer 153P may be formed using a deposition process to constitute the second pad layer 153 of the channel pad 150 of FIG. 7.

Referring to FIG. 37, a portion of each of the channel insulating layer 145 and the second pre-pad layer 153P disposed on top of the upper capping layer 172 may be removed. To this end, a planarization process may be performed until the upper surface of the upper capping layer 172 is exposed. Accordingly, the upper surface of the second pad layer 153 and the upper surface of the upper capping layer 172 may be coplanar with each other. Accordingly, the second polysilicon layer 154, the first pad layer 151, and the second pad layer 153 of the channel pad 150 of FIG. 7 may be formed.

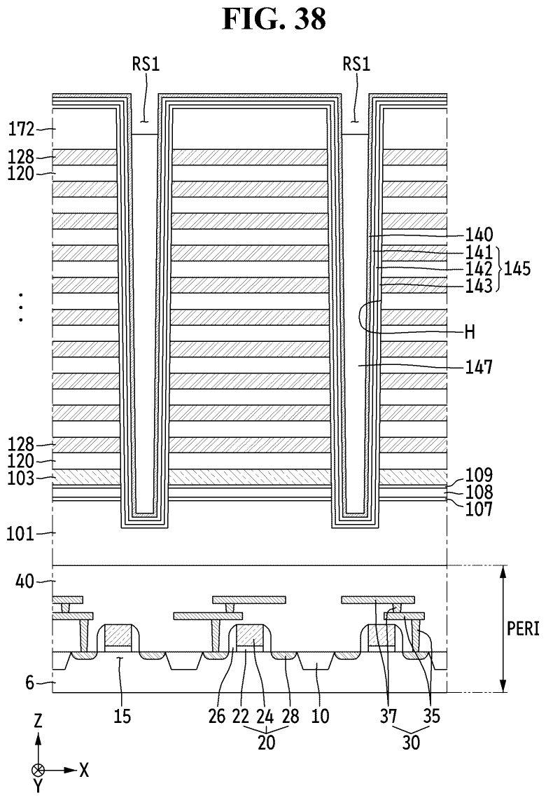

FIGS. 38 to 45 are other diagrams of intermediate structures corresponding to intermediate steps of a method for manufacturing a semiconductor memory device according to some embodiments. For the convenience of description, components the same as those described above with reference to FIG. 21 to FIG. 37 are briefly described or descriptions thereof are omitted. For reference, FIG. 38 to FIG. 45 are diagrams of intermediate structures corresponding to intermediate steps of a method for manufacturing a semiconductor memory device as illustrated in FIG. 10.

FIG. 38 is a diagram showing a process after the peripheral circuit structure PERI, the lower pattern layer 101, the horizontal sacrificial layers 107, 108, and 109, the upper pattern layer 103, the interlayer insulating layers 120, the sacrificial layers 128, and the upper capping layer 172 of FIG. 21 are formed.

Referring to FIG. 38, the channel hole H extending through the stack structure of the interlayer insulating layers 120 and the sacrificial layers 128 may be formed, and then, the channel insulating layer 145, the channel layer 140, and the core insulating layer 147 may be formed within the channel hole H. Thereafter, a portion of the core insulating layer 147 may be removed from a top thereof to form the first recess RS1 exposing a portion of a side surface of the upper channel layer 140. For example, removing the portion of the core insulating layer 147 from the top thereof may be performed using a wet etching process or a dry etching process. For example, a vertical level of a lower end of the first recess RS1 may be higher than a vertical level of the upper sacrificial layer 128.

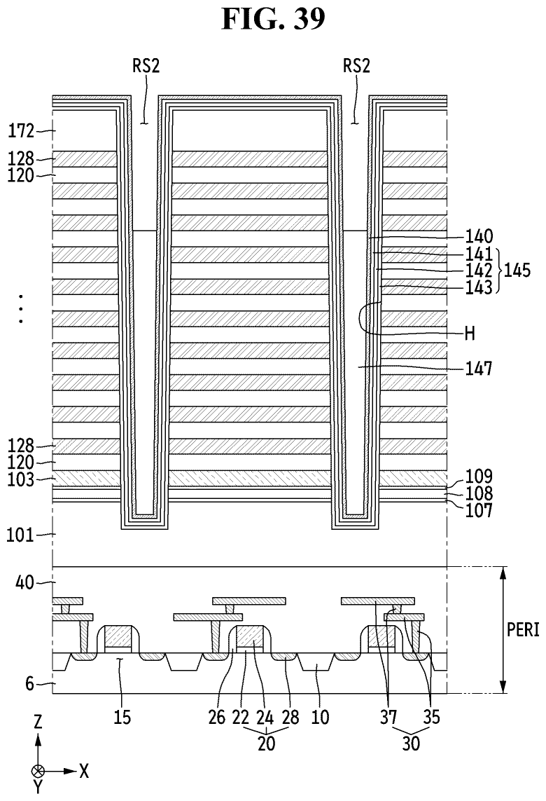

Referring to FIG. 39, the core insulating layer 147 may be further removed from the bottom surface of the first recess RS1 to form the second recess RS2. The second recess RS2 may further expose the side surface of the channel layer 140. For example, further removing the core insulating layer 147 may be performed using a wet etching process or a dry etching process. A depth of the second recess RS2 may be determined based on a level in the third direction Z of the bottom surface of the channel pad 150. For example, a lower end of the second recess RS2 may be positioned at a vertical level lower than a vertical level of the upper sacrificial layer 128.

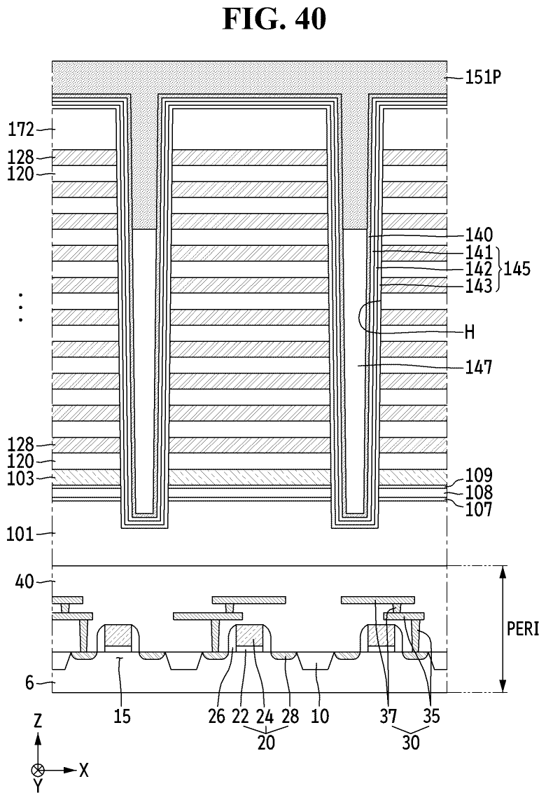

Referring to FIG. 40, the first pre-pad layer 151P may be formed on the core insulating layer 147. The first pre-pad layer 151P may be formed within the second recess RS2. The first pre-pad layer 151P may be deposited on the core insulating layer 147 to constitute the first pad layer 151 of the channel pad 150 of FIG. 10.

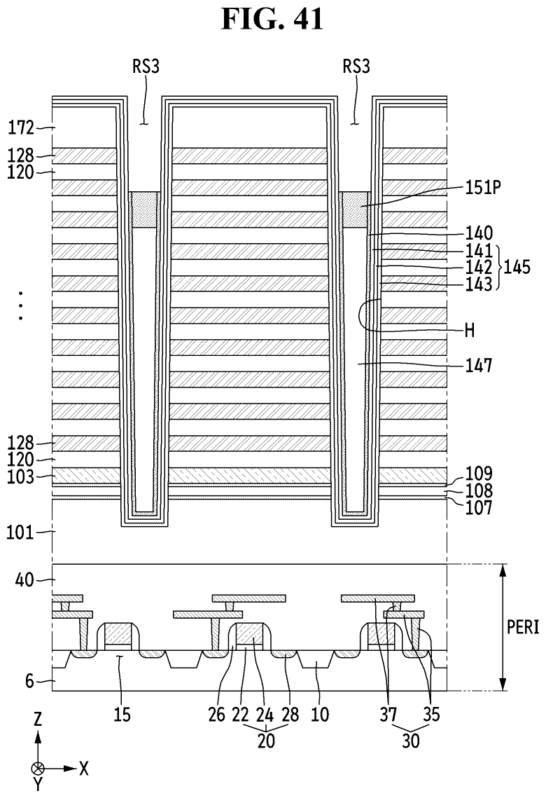

Referring to FIG. 41, the channel layer 140 and the first pre-pad layer 151P may be partially removed from a top thereof to form a third recess RS3. The third recess RS3 may expose a portion of the inner side surface of the tunneling layer 141, an upper surface of the channel layer 140, and an upper surface of the first pre-pad layer 151P. Removing the portion of each of the channel layer 140 and the first pre-pad layer 151P may be performed using, for example, a wet etching process or a dry etching process.

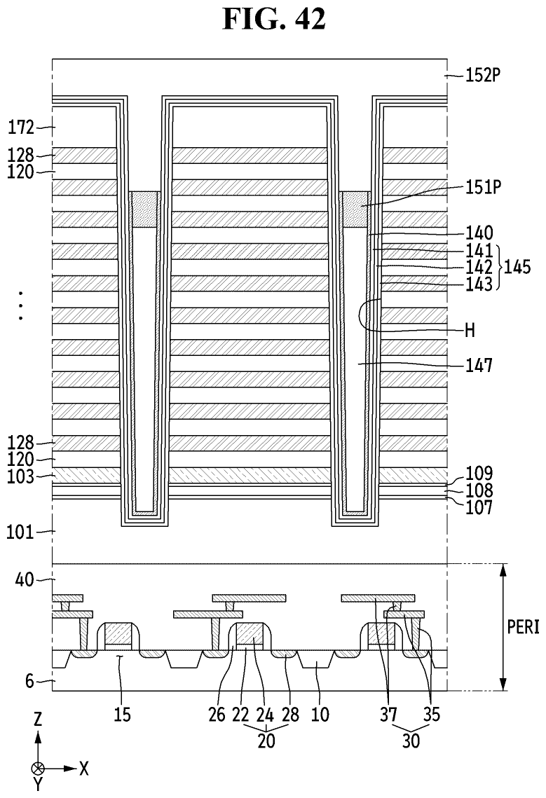

Referring to FIG. 42, the second pre-polysilicon layer 152P may be formed on the portion of the inner side surface of the tunneling layer 141 and the bottom surface of the third recess RS3. The second pre-polysilicon layer 152P may be formed on the portion of the inner side surface of the tunneling layer 141, the upper surface of the channel layer 140, and the upper surface of the first pre-pad layer 151P. The second pre-polysilicon layer 152P may be formed using a deposition process or an epitaxial growth process to constitute the first polysilicon layer 152 of the channel pad 150 of FIG. 10.

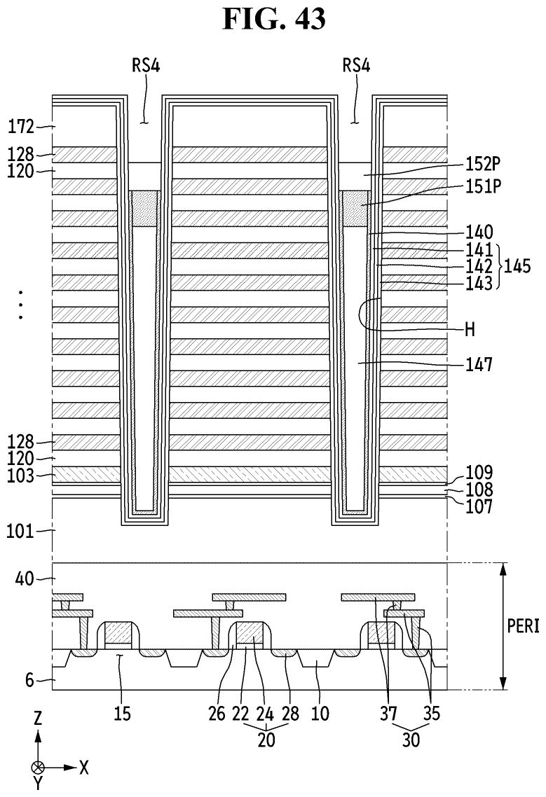

Referring to FIG. 43, a portion of the second pre-polysilicon layer 152P may be removed from a top thereof to form a fourth recess RS4. The fourth recess RS4 may expose a portion of the inner side surface of the tunneling layer 141 and an upper surface of the second pre-polysilicon layer 152P. Removing a portion of the second pre-polysilicon layer 152P may be performed, for example, using a wet etching process or a dry etching process.

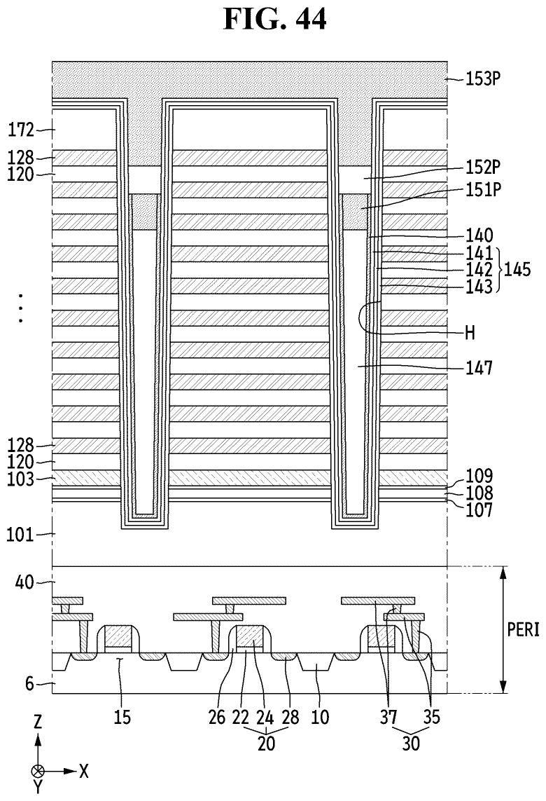

Referring to FIG. 44, the second pre-pad layer 153P may be formed on the second pre-polysilicon layer 152P. The second pre-pad layer 153P may be formed in a space of the fourth recess RS4 remaining after the second pre-polysilicon layer 152P has been formed therein. The second pre-pad layer 153P may be deposited on the second pre-polysilicon layer 152P to constitute the second pad layer 153 of the channel pad 150 of FIG. 10.

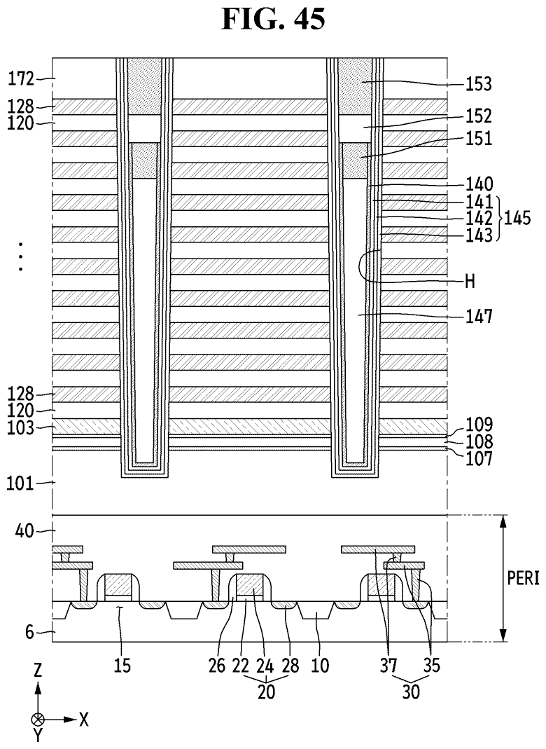

Referring to FIG. 45, a portion of each of the channel insulating layer 145 and the second pre-pad layer 153P disposed on top of the upper capping layer 172 may be removed. To this end, a planarization process may be performed until the upper surface of the upper capping layer 172 is exposed. Accordingly, the upper surface of the second pad layer 153 and the upper surface of the upper capping layer 172 may be coplanar with each other. Accordingly, the first pad layer 151, the first polysilicon layer 152, and the second pad layer 153 of the channel pad 150 of FIG. 10 may be formed.

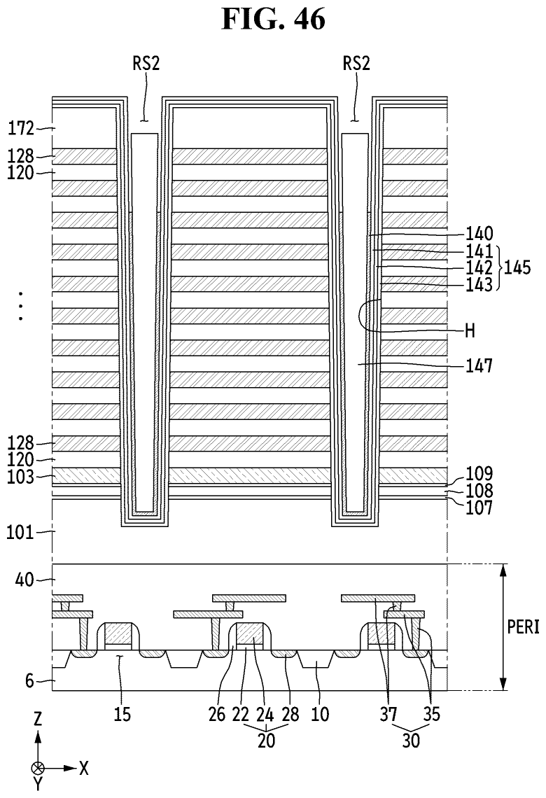

FIGS. 46 to 51 are other diagrams of example intermediate structures corresponding to intermediate steps of a method for manufacturing a semiconductor memory device according to some embodiments. For convenience of description, components the same as those described above with reference to FIGS. 21 to 45 are briefly described or descriptions thereof are omitted. For reference, FIGS. 46 to 51 are diagrams of intermediate structures corresponding to intermediate steps of a method for manufacturing the semiconductor memory device as illustrated in FIG. 14.

FIG. 46 is a diagram showing a process after the first recess RS1 of FIG. 38 is formed.

Referring to FIG. 46, the second recess RS2 may be formed by further removing both opposing side portions of the channel layer 140 adjacent to the channel insulating layer 145 from the bottom surface of the first recess RS1. The second recess RS2 may further expose the upper surface of the channel layer 140 and the portion of the side surface of the tunneling layer 141. For example, further removing both opposing side portions of the channel layer 140 may be performed using a wet etching process or a dry etching process. The depth of the second recess RS2 may be determined based on a level in the third direction Z of the bottom surface of the channel pad 150. For example, a lower end of the second recess RS2 may be positioned at a vertical level lower than a vertical level of the upper sacrificial layer 128.

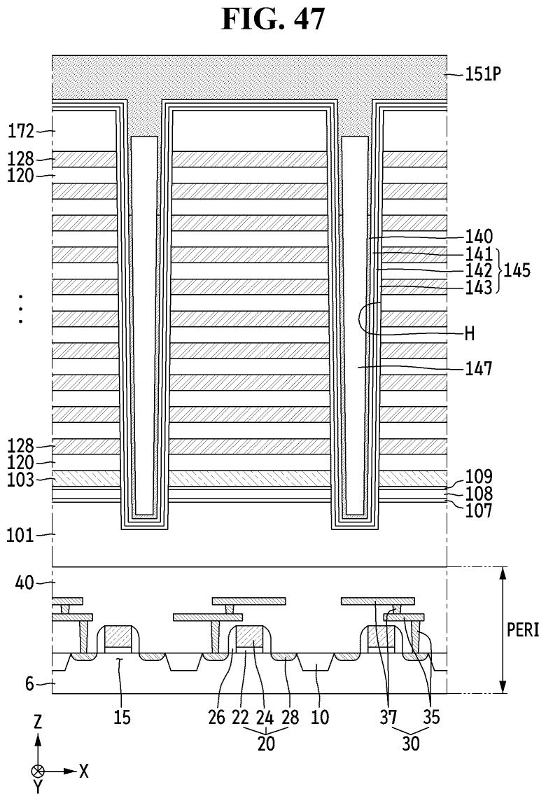

Referring to FIG. 47, the first pre-pad layer 151P may be formed on the channel layer 140 and the core insulating layer 147. The first pre-pad layer 151P may be formed in the second recess RS2. The first pre-pad layer 151P may be in contact with the upper surface of the core insulating layer 147, the inner side surface of the core insulating layer 147, the upper surface of the channel layer 140, and the portion of the side surface of the tunneling layer 141. The first pre-pad layer 151P may be deposited on the core insulating layer 147 to constitute the first pad layer 151 of the channel pad 150 of FIG. 14.

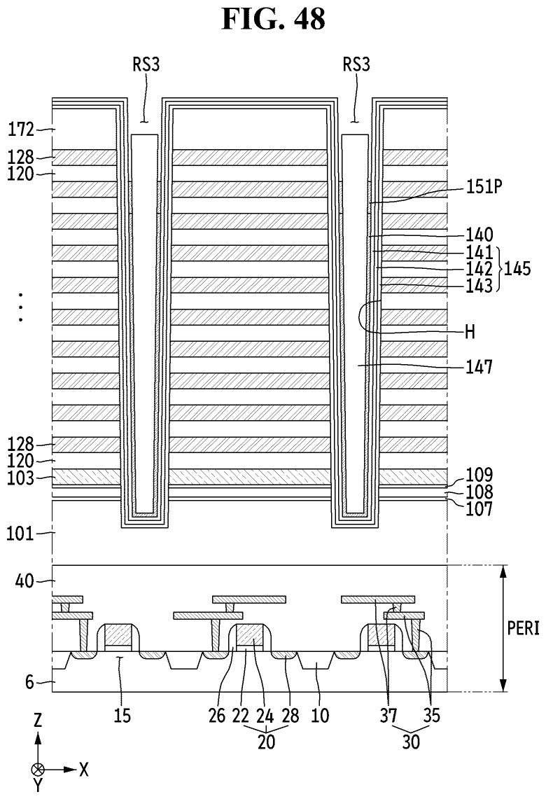

Referring to FIG. 48, a portion of the first pre-pad layer 151P may be removed from a top thereof to form the third recess RS3. The third recess RS3 may expose the upper surface of the core insulating layer 147, the inner side surface of the core insulating layer 147, a portion of the inner side surface of the tunneling layer 141, and the upper surface of the first pre-pad layer 151P. Removing the portion of the first pre-pad layer 151P may be performed, for example, using a wet etching process or a dry etching process.

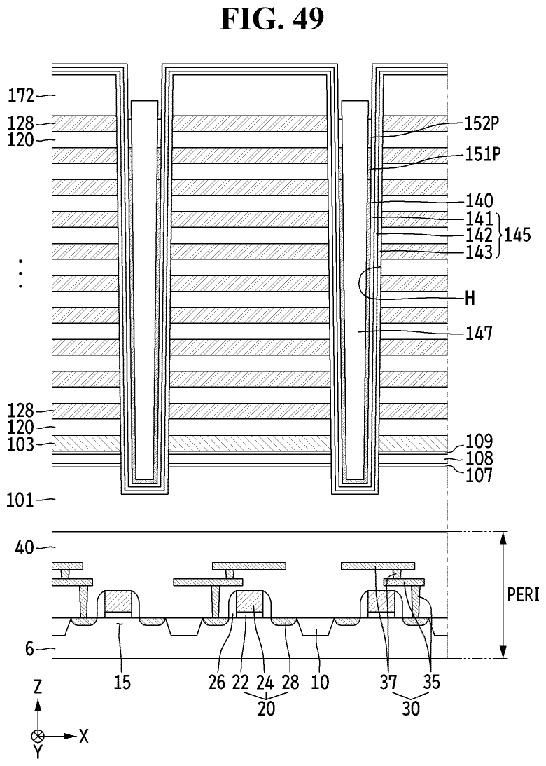

Referring to FIG. 49, the second pre-polysilicon layer 152P may be formed on the first pre-pad layer 151P. The upper surface of the second pre-polysilicon layer 152P may be positioned at a lower vertical level than a vertical level of the upper surface of the core insulating layer 147. The second pre-polysilicon layer 152P may be formed on the inner side surface of the tunneling layer 141 and on the first pre-pad layer 151P. The second pre-polysilicon layer 152P may be formed on a portion of the inner side surface of the tunneling layer 141 and the upper surface of the first pre-pad layer 151P. The second pre-polysilicon layer 152P may be formed using a deposition process or an epitaxial growth process to constitute the first polysilicon layer 152 of the channel pad 150 of FIG. 14.

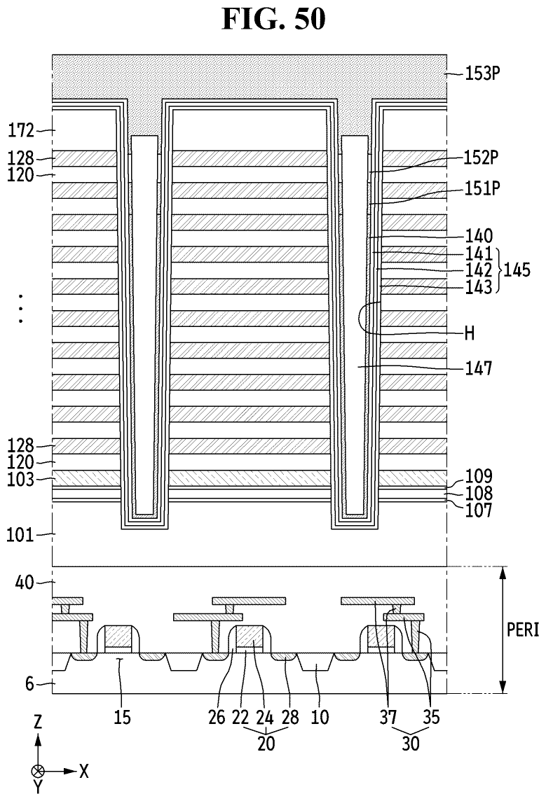

Referring to FIG. 50, the second pre-pad layer 153P may be formed on the second pre-polysilicon layer 152P. The second pre-pad layer 153P may be in contact with the upper surface of the second pre-polysilicon layer 152P. The second pre-pad layer 153P may be in contact with a portion of the inner side surface of the tunneling layer 141, a portion of the inner side surface of the core insulating layer 147, an upper surface of the core insulating layer 147, and an upper surface of the second pre-polysilicon layer 152P. The second pre-pad layer 153P may be deposited on the second pre-polysilicon layer 152P to constitute the second pad layer 153 of the channel pad 150 of FIG. 14.

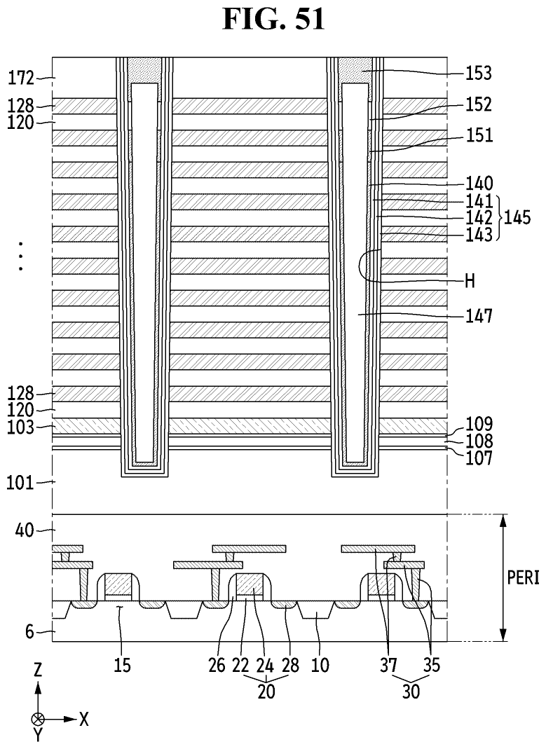

Referring to FIG. 51, a portion of each of the channel insulating layer 145 and the second pre-pad layer 153P disposed on top of the upper capping layer 172 may be removed. To this end, a planarization process may be performed until the upper surface of the upper capping layer 172 is exposed. Accordingly, the upper surface of the second pad layer 153 and the upper surface of the upper capping layer 172 may be coplanar with each other. Accordingly, the first pad layer 151, the first polysilicon layer 152, and the second pad layer 153 of the channel pad 150 of FIG. 14 may be formed.

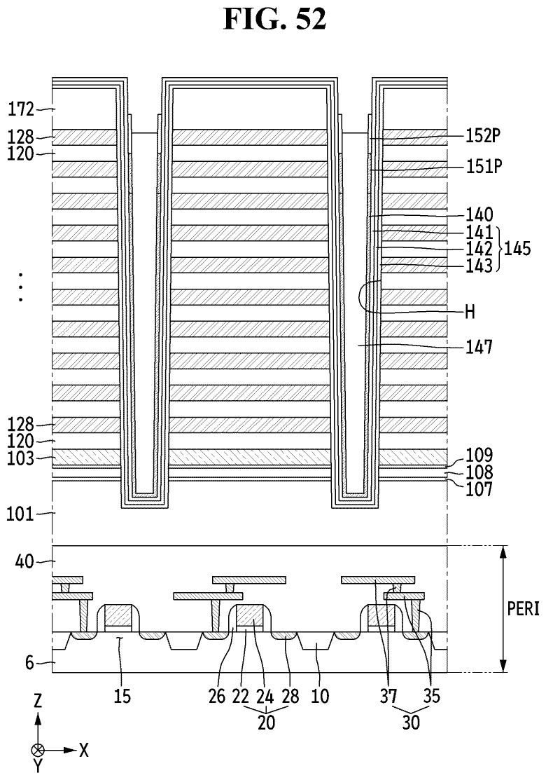

FIGS. 52 to 54 are other diagrams of example intermediate structures corresponding to intermediate steps of a method for manufacturing a semiconductor memory device according to some embodiments. For convenience of description, components the same as those described above with reference to FIGS. 21 to 51 are briefly described or descriptions thereof are omitted. For reference, FIGS. 52 to 54 are diagrams of intermediate structures corresponding to intermediate steps of a method for manufacturing the semiconductor memory device as illustrated in FIG. 16.

FIG. 52 is a diagram showing a process after the third recess RS3 of FIG. 48 is formed.

Referring to FIG. 52, the second pre-polysilicon layer 152P may be formed on the first pre-pad layer 151P. The upper surface of the second pre-polysilicon layer 152P may be positioned at a higher vertical level than that of the upper surface of the core insulating layer 147. The second pre-polysilicon layer 152P may be formed on the inner side surface of the tunneling layer 141 and on the first pre-pad layer 151P. The second pre-polysilicon layer 152P may be formed on a portion of the inner side surface of the tunneling layer 141 and on the upper surface of the first pre-pad layer 151P. The second pre-polysilicon layer 152P may be formed using a deposition process or an epitaxial growth process to constitute the first polysilicon layer 152 of the channel pad 150 of FIG. 16.

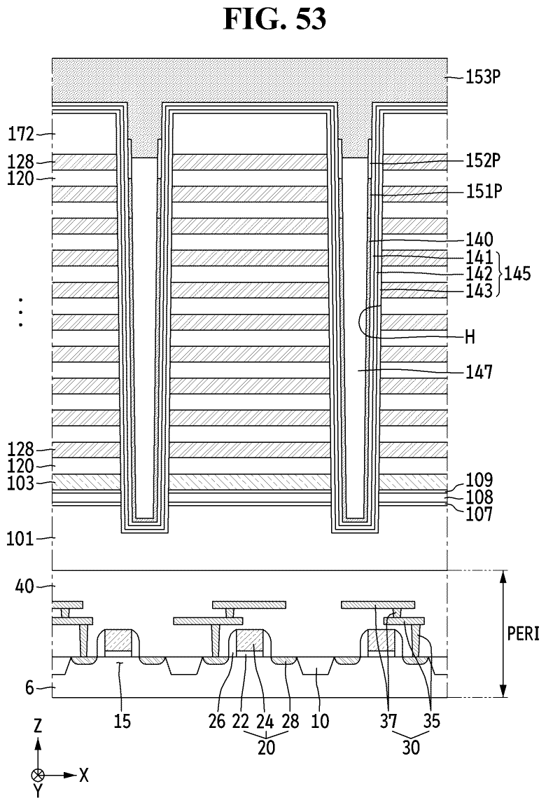

Referring to FIG. 53, the second pre-pad layer 153P may be formed on the second pre-polysilicon layer 152P. The second pre-pad layer 153P may be in contact with the upper surface and the inner side surface of the second pre-polysilicon layer 152P. The second pre-pad layer 153P may be in contact with a portion of the inner side surface of the tunneling layer 141, the upper surface of the second pre-polysilicon layer 152P, a portion of the inner side surface of the second pre-polysilicon layer 152P, and the upper surface of the core insulating layer 147. The second pre-pad layer 153P may be deposited on the second pre-polysilicon layer 152P to constitute the second pad layer 153 of the channel pad 150 of FIG. 16.

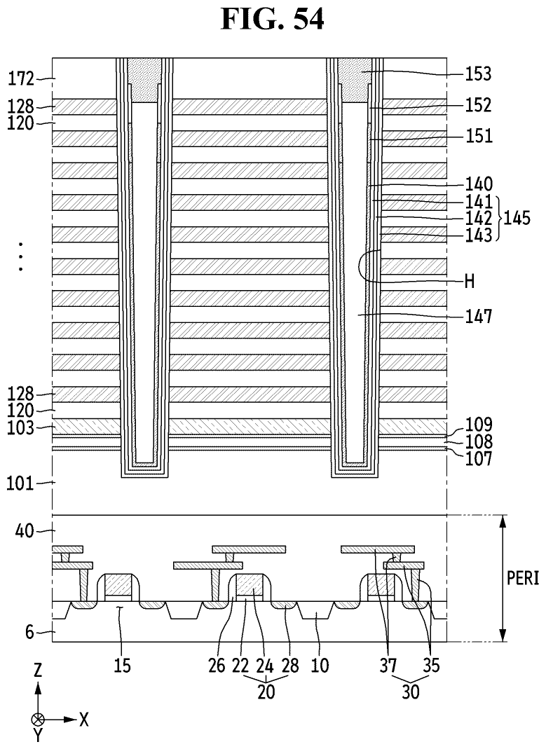

Referring to FIG. 54, a portion of each of the channel insulating layer 145 and the second pre-pad layer 153P disposed on top of the upper capping layer 172 may be removed. To this end, a planarization process may be performed until the upper surface of the upper capping layer 172 is exposed. Accordingly, the upper surface of the second pad layer 153 and the upper surface of the upper capping layer 172 may be coplanar with each other. Accordingly, the first pad layer 151, the first polysilicon layer 152, and the second pad layer 153 of the channel pad 150 of FIG. 16 may be formed.

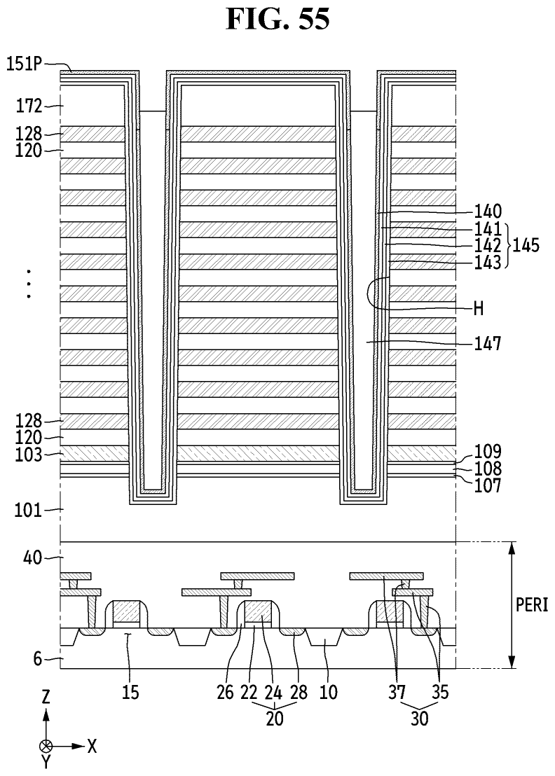

FIGS. 55 to 61 are other diagrams of intermediate structures corresponding to intermediate steps of a method for manufacturing a semiconductor memory device according to some embodiments. For convenience of description, contents components the same as those described above with reference to FIGS. 21 to 54 are briefly described or descriptions thereof are omitted. For reference, FIGS. 55 to 61 are diagrams of intermediate structures corresponding to intermediate steps of a method for manufacturing the semiconductor memory device as illustrated in FIG. 18.

FIG. 55 is a diagram showing a process after the first recess RS1 of FIG. 38 is formed.

Referring to FIG. 55, a portion of each of both opposing side portions of the upper channel layer 140 disposed between the core insulating layer 147 and the channel insulating layer 145 may be removed, and then, the first pre-pad layer 151P may be formed within a space defined by removing the portion. For example, the first pre-pad layer 151P may be formed in an ion implantation process. The upper surface of the core insulating layer 147 may be located at a higher vertical level than that of the upper sacrificial layer 128.

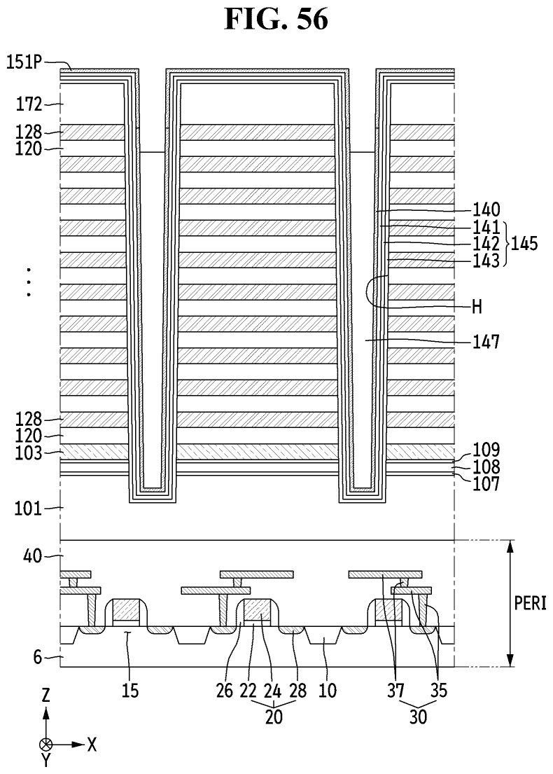

Referring to FIG. 56, a top portion of the core insulating layer 147 may be further removed, such that the side surface of the first pre-pad layer 151P and the side surface of the channel layer 140 may be further exposed. The upper surface of the core insulating layer 147 may be located at a vertical level lower than a vertical level of the upper sacrificial layer 128. The upper surface of the core insulating layer 147 may be located at a vertical level lower than that of the lower surface of the first pre-pad layer 151P. The further removal of the top portion of the core insulating layer 147 may be performed in a wet etching or dry etching process.

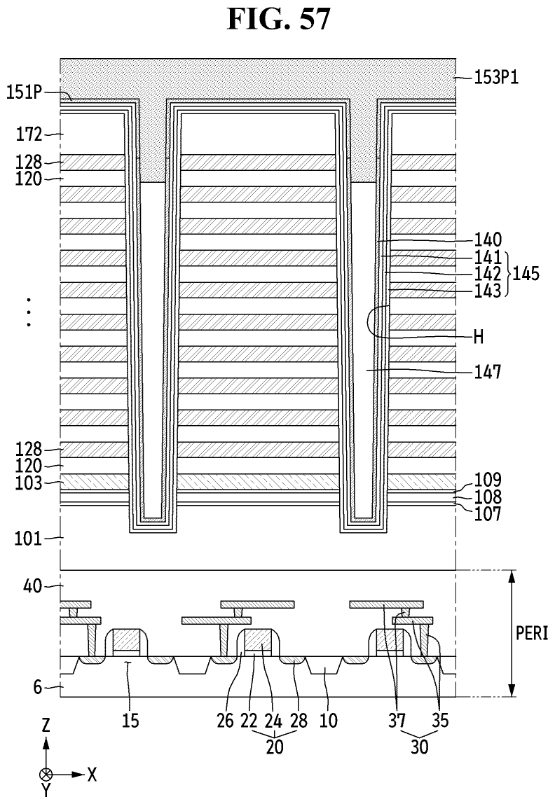

Referring to FIG. 57, a second_first pre-pad layer 153P1 may be formed on the side surface of the first pre-pad layer 151P, the portion of the side surface of the channel layer 140, and the upper surface of the core insulating layer 147.

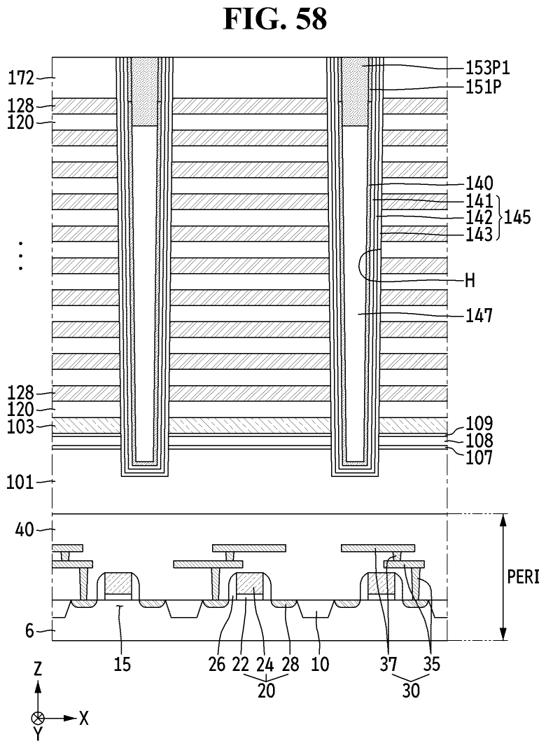

Referring to FIG. 58, a portion of each of the channel insulating layer 145, the first pre-pad layer 151P, and the second_first pre-pad layer 153P1 disposed on top of the upper capping layer 172 may be removed. To this end, a planarization process may be performed until the upper surface of the upper capping layer 172 is exposed. Accordingly, an upper surface of the second_first pre-pad layer 153P1 and the upper surface of the upper capping layer 172 may be coplanar with each other.

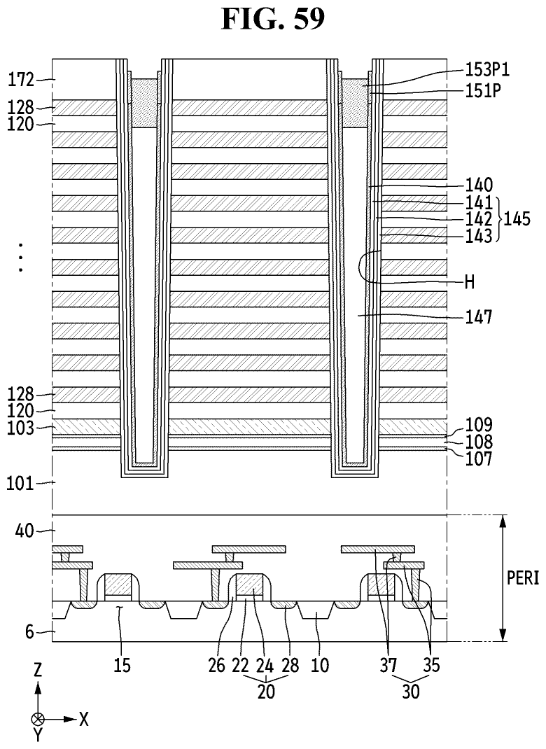

Referring to FIG. 59, a top portion of the second_first pre-pad layer 153P1 may be further removed to expose the upper surface of the first pre-pad layer 151P, the portion of the inner side surface of the first pre-pad layer 151P, and the upper surface of the core insulating layer 147. The further removal of the top portion of the second_first pre-pad layer 153P1 may be performed in a wet etching or dry etching process.

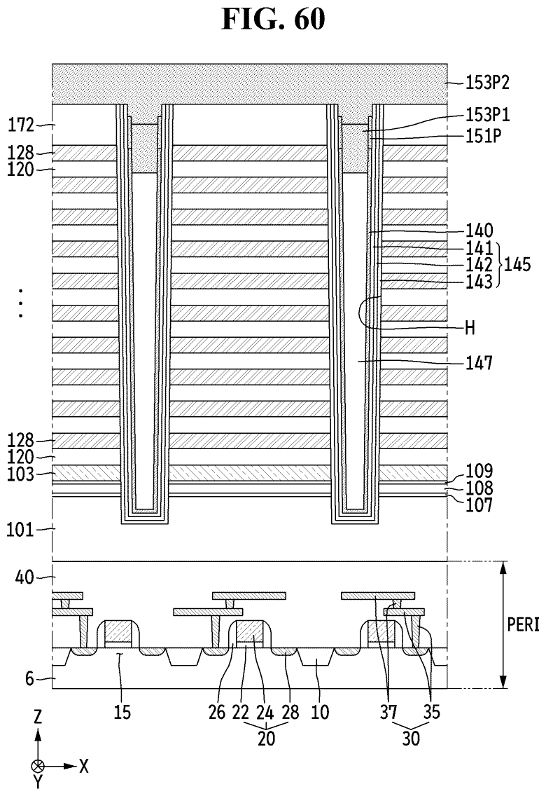

Referring to FIG. 60, a second_second pre-pad layer 153P2 may be formed on the second_first pre-pad layer 153P1. The second_second pre-pad layer 153P2 may be formed on the upper surface of the first pre-pad layer 151P, the portion of the inner side surface of the first pre-pad layer 151P, and the upper surface of the core insulating layer 147.

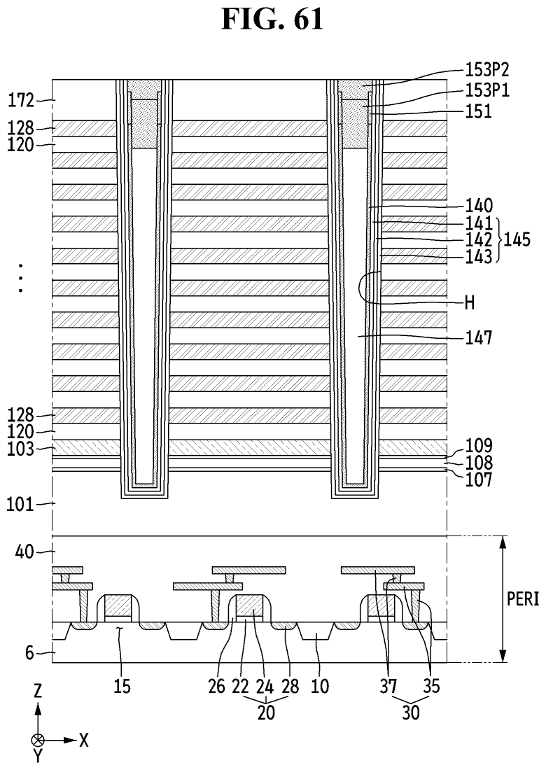

Referring to FIG. 61, a portion of the second_second pre-pad layer 153P2 disposed on top of the upper capping layer 172 may be removed. To this end, a planarization process may be performed until the upper surface of the upper capping layer 172 is exposed. Accordingly, an upper surface of the second_second pre-pad layer 153P2 and the upper surface of the upper capping layer 172 may be coplanar with each other. Accordingly, the first pad layer 151 and the second pad layer 153 of the channel pad 150 of FIG. 18 may be formed.

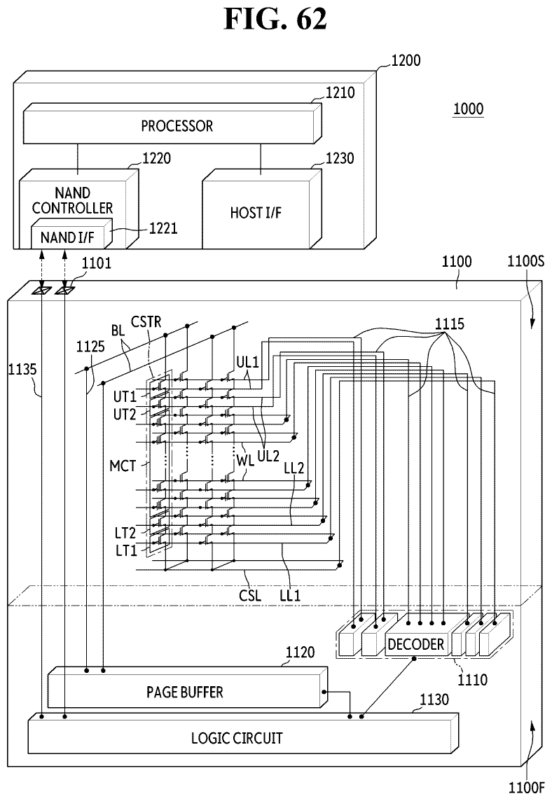

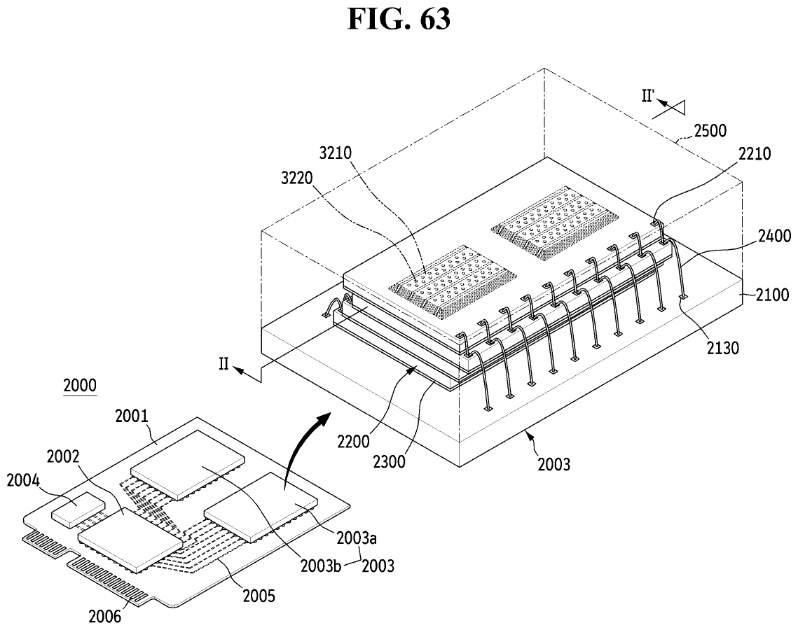

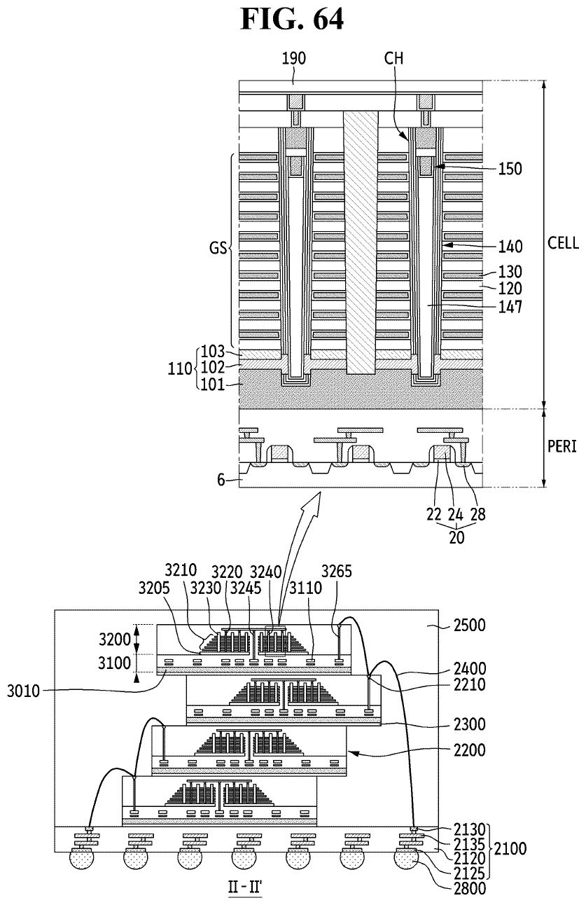

FIG. 62 is an example block diagram for illustrating an electronic system according to some embodiments. FIG. 63 is an example perspective view for illustrating an electronic system according to some embodiments. FIG. 64 is a schematic cross-sectional view cut along a line II-II′ of FIG. 63. For convenience of description, components the same as those described above with reference to FIGS. 1 to 20 are briefly described or descriptions thereof are omitted.

Referring to FIG. 62, an electronic system 1000 may include a semiconductor memory device 1100 and a controller 1200 electrically connected to the semiconductor memory device 1100. The electronic system 1000 may be a storage device including one or a plurality of semiconductor memory devices 1100 or an electronic device including a storage device. For example, the electronic system 1000 may be a solid state drive device (SSD), a Universal Serial Bus (USB), a computing system, a medical device, or a communication device including one or a plurality of semiconductor memory devices 1100.

The semiconductor memory device 1100 may be a nonvolatile memory device, for example, a NAND flash memory device as described above with reference to FIGS. 1 to 20. The semiconductor memory device 1100 may include a first structure 1100F and a second structure 1100S on the first structure 1100F. In some embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may vary depending on embodiments.

In some embodiments, the upper transistors UT1 and UT2 may include a string select transistor, and the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, respectively, and the upper gate lines UL1, UL2 may be gate electrodes of the upper transistors UT1 and UT2, respectively.

In some embodiments, the lower transistors LT1 and LT2 may include a lower erase control transistor LT1 and aground select transistor LT2 serially connected to each other. The upper transistors UT1 and UT2 may include a string select transistor UT1 and an upper erase control transistor UT2 serially connected to each other. At least one of the lower erase control transistor LT1 and the upper erase control transistor UT1 may be used for an erase operation of erasing data stored in the memory cell transistors MCT using the GIDL phenomenon.

Each of the at least one of the lower gate electrodes 130LE1 and 130LE2 of FIG. 3 may correspond to a corresponding lower gate line LL1 and LL2, each of the at least one of the upper gate electrodes 130UE1 and 130UE2 of FIG. 3 may correspond to a corresponding upper gate lines UL1 and UL2, and the middle gate electrodes 130M of FIG. 3 may correspond to the word lines WL.

The first lower gate electrode 130LE1 of FIG. 3 may be the gate electrode of the lower erase control transistor LT1. The second lower gate electrode 130LE2 may be the gate electrode of the ground select transistor LT2. The first upper gate electrode 130UE1 of FIG. 3 may be the gate electrode of the upper erase control transistor UT1. The second upper gate electrode 130UE2 may be the gate electrode of the string select transistor UT2.

The common source line CSL, the first and second lower gate lines LL1 and LL2, the word lines WL, and the first and second upper gate lines UL1 and UL2 may be electrically connected to the decoder circuit 1110 via first connection wirings 1115 extending from the first structure 1100F to the second structure 1100S. The bit lines BL may be electrically connected to the page buffer 1120 via second connection wirings 1125 extending from the first structure 1100F to the second structure 1100S.

In the first structure 1100F, the decoder circuit 1110 and the page buffer 1120 may perform a control operation on at least one select memory cell transistor among a plurality of memory cell transistors MCT. The decoder circuit 1110 and the page buffer 1120 may be controlled by the logic circuit 1130. The semiconductor memory device 1000 may communicate with the controller 1200 through an input/output pad 1101 electrically connected to the logic circuit 1130. The input/output pad 1101 may be electrically connected to the logic circuit 1130 via an input/output connection wiring 1135 extending from the first structure 1100F to the second structure 1100S.

The controller 1200 may include a processor 1210, a NAND controller 1220, and a host interface 1230. According to embodiments, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the semiconductor memory device 1100. The NAND controller 1220 may include a NAND interface 1221 that processes communication with the semiconductor memory device 1100. Via the NAND interface 1221, a control command for controlling the semiconductor memory device 1100, data to be written to memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. Upon receiving a control command from an external host via the host interface 1230, the processor 1210 may control the semiconductor memory device 1100 in response to the control command.

Referring to FIG. 63, an electronic system 2000 according to some embodiments of the present disclosure may include a main substrate 2001, a controller 2002 mounted on the main substrate 2001, at least one semiconductor package 2003, and at least one DRAM 2004. The semiconductor package 2003 and he DRAM 2004 may be connected to the controller 2002 via line patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some embodiments, the electronic system 2000 may operate using power supplied from the external host via the connector 2006. The electronic system 2000 may further include a power management integrated circuit (PMIC) for distributing power supplied from the external host to the controller 2002 and the semiconductor package 2003.

The controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a bottom face of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each of the semiconductor chips 2200 may include an input/output pad 2210. The input/output pad 2210 may correspond to the input/output pad 1101 of FIG. 62. Each of the semiconductor chips 2200 may include gate stack structures 3210 and channel structures 3220. Each of the semiconductor chips 2200 may include the semiconductor memory device as described above with reference to FIGS. 1 to 20.

In some embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments, in each of the first semiconductor package 2003a and the second semiconductor package 2003b, the semiconductor chips 2200 may be electrically connected to each other via a connection structure including a through electrode (e.g., Through Silicon Via: TSV) instead of the connection structure 2400 using the bonding wire scheme.

In some embodiments, the controller 2002 and the semiconductor chips 2200 may be included in one package. In some embodiments, the controller 2002 and the semiconductor chips 2200 may be mounted on a separate interposer substrate different from the main substrate 2001, and the controller 2002 and the semiconductor chips 2200 may be connected to each other via a line formed in the interposer substrate.

Referring to FIG. 64, in the semiconductor package 2003, the package substrate 2100 may be embodied as a printed circuit board. The package substrate 2100 may include a package substrate body 2120, the package upper pads 2130 disposed on a top face of the package substrate body 2120, package lower pads 2125 disposed on a bottom face of the package substrate body 2120, or exposed through the bottom face thereof, and internal lines 2135 disposed in the package substrate body 2120 so as to electrically connect the upper pads 2130 and the lower pads 2125 to each other. The upper pads 2130 may be electrically connected to the connection structures 2400. The lower pads 2125 may be connected to the line patterns 2005 of the main substrate 2010 of the electronic system 2000 via conductive connectors 2800 as shown in FIG. 63.

Each of the semiconductor chips 2200 may include for example, a semiconductor substrate 3010 and a first structure 3100 and a second structure 3200 sequentially stacked on the semiconductor substrate 3010. The first structure 3100 may include a peripheral circuit area including peripheral wirings 3110. The second structure 3200 may include a common source line 3205, a gate stack structure 3210 on the common source line 3205, channel structures 3220 and isolation areas 3230 extending through the gate stack structure 3210, and bit lines 3240 electrically connected to the memory channel structures 3220. As described above with reference to FIGS. 1 to 20, the semiconductor memory device according to some embodiments may include the semiconductor substrate 6, the circuit elements 20, the pattern structure 110, the stack structure GS including the gate electrodes 130, the channel structures CH, and the bit line 190 in each of the semiconductor chips 2200. Each of the channel structures CH may include the channel pad 150, and the channel pad 150 may include the second polysilicon layer 154, the first pad layer 151, the first polysilicon layer 152, and the second pad layer 153. According to an embodiment, the channel pad 150 may not include the second polysilicon layer 154 and/or the first polysilicon layer 152. Alternatively, according to an embodiment, the channel pad 150 may include the first pad layer 151 and the first polysilicon layer 152 extending in a line shape.

Each of the semiconductor chips 2200 may include for example a through-wiring 3245 that is electrically connected to the peripheral wirings 3110 of the first structure 3100 and extends into the second structure 3200. The through-wiring 3245 may be disposed out of the gate stack structure 3210 and may further extend through the gate stack structure 3210. Each of the semiconductor chips 2200 may further include the input/output pad 2210 (see FIG. 63) that is electrically connected to the peripheral wirings 3110 of the first structure 3100.

Although the present disclosure has been described with reference to the attached drawings, the present invention is not limited to the above embodiments, but may be manufactured in various different forms, and a person having ordinary skill in the art to which the present disclosure belongs will understand that the present disclosure may be implemented in other specific forms without changing the technical idea or essential features of the present disclosure. Therefore, the embodiments described above should be understood as illustrative in all respects and not restrictive.

What is claimed is:

1. A semiconductor memory device comprising:
a substrate;
a stack structure disposed on the substrate, wherein the stack structure includes a plurality of gate electrodes and a plurality of insulating layers each gate electrode of the plurality of gate electrodes and insulating layer of the plurality of insulating layers being alternately stacked on top of each other in a first direction perpendicular to an upper surface of the substrate;
a channel structure extending through the stack structure and extending in the first direction; and
a bit line connected to the channel structure via a contact plug disposed on the channel structure,
wherein the channel structure includes a core insulating layer, a channel layer disposed on a side surface of the core insulating layer, a channel insulating layer extending in the first direction to be disposed between the channel layer and the plurality of gate electrodes, and a channel pad disposed on top of the core insulating layer to be in contact with the channel layer,
wherein the channel pad includes:
a first pad layer including a material of a first conductivity; and
a second pad layer disposed on top of the first pad layer in the first direction and including a material of a second conductivity different from the first conductivity,
wherein an outermost side surface of the second pad layer is in contact with the channel insulating layer.

2. The semiconductor memory device of claim 1, wherein a side surface of the first pad layer is not in contact with the second pad layer.

3. The semiconductor memory device of claim 1, wherein a first width of the first pad layer is smaller than a second width of the second pad layer.

4. The semiconductor memory device of claim 1,
wherein the channel layer is in contact with a side surface of the first pad layer, and
wherein a lower surface of the first pad layer and the core insulating layer are in contact with each other.

5. The semiconductor memory device of claim 1, wherein the first pad layer and the second pad layer are in contact with each other.

6. The semiconductor memory device of claim 1,
wherein the channel pad further includes a first semiconductor material layer disposed between the first pad layer and the second pad layer, wherein the first semiconductor material layer is not doped with impurities, and
wherein each of an upper surface of the first pad layer and a lower surface of the second pad layer are in contact with the first semiconductor material layer.

7. The semiconductor memory device of claim 1,
wherein the channel pad further includes a second semiconductor material layer disposed between the channel layer and the first pad layer, wherein the second semiconductor material layer is not doped with impurities, and
wherein the second semiconductor material layer is disposed along and on a portion of a side surface of the channel layer and an upper surface of the core insulating layer.

8. The semiconductor memory device of claim 7, wherein a first vertical level in the first direction of an upper surface of the second semiconductor material layer surface is equal to a second vertical level in the first direction of an upper surface of the channel layer.

9. The semiconductor memory device of claim 1, wherein the second pad layer at least partially overlaps an uppermost gate electrode among the plurality of gate electrodes.

10. The semiconductor memory device of claim 1, wherein the second pad layer surrounds a portion of a side wall and an upper surface of the core insulating layer.

11. The semiconductor memory device of claim 1, wherein the second pad layer is T-shaped.

12. The semiconductor memory device of claim 1,
wherein the first pad layer includes polysilicon doped with P-type impurities, and
wherein the second pad layer includes polysilicon doped with N-type impurities.

13. The semiconductor memory device of claim 1,
wherein the first pad layer includes polysilicon doped with N-type impurities, and
wherein the second pad layer includes polysilicon doped with P-type impurities.

14. A semiconductor memory device comprising:
a substrate;
a stack structure disposed on the substrate, wherein the stack structure includes a plurality of gate electrodes and a plurality of insulating layers each gate electrode of the plurality of gate electrodes and insulating layer of the plurality of insulating layers being alternately stacked on top of each other in a vertical direction;
a channel structure extending through the stack structure and extending in the vertical direction; and
a bit line connected to the channel structure via a contact plug disposed on the channel structure,
wherein the channel structure includes a core insulating layer, a channel layer disposed on a side surface of the core insulating layer, a channel insulating layer extending in the vertical direction to be disposed between the channel layer and the plurality of gate electrodes, and a channel pad disposed on top of the core insulating layer to be in contact with the channel layer,
wherein the channel pad includes:
a first pad layer including polysilicon doped with a first conductivity impurity;
a second pad layer disposed on top of the first pad layer and including polysilicon doped with a second conductivity different from the first conductivity; and
a first polysilicon layer disposed between the first and second pad layers,
wherein the first polysilicon layer is not doped with an impurity, and
wherein a side surface of the first pad layer is not in contact with the second pad layer.

15. The semiconductor memory device of claim 14, wherein an upper surface of the channel layer is in contact with the first polysilicon layer.

16. The semiconductor memory device of claim 14, wherein an upper surface of the channel layer is in contact with the first pad layer.

17. The semiconductor memory device of claim 14, wherein the channel pad further includes a second polysilicon layer disposed between the channel layer and the first pad layer and disposed along and on a portion of a side surface of the channel layer and an upper surface of the core insulating layer, wherein the second polysilicon layer is not doped with impurities.

18. The semiconductor memory device of claim 14,
wherein the channel layer extends in the vertical direction to be disposed between the core insulating layer and the channel insulating layer,
wherein the first pad layer is disposed on top of the channel layer and between the core insulating layer and the channel insulating layer,
wherein the first polysilicon layer is disposed on top of the first pad layer and between the core insulating layer and the channel insulating layer, and
wherein a third vertical level of an upper surface of the core insulating layer is higher than a fourth vertical level of an upper surface of the first polysilicon layer.

19. The semiconductor memory device of claim 14,
wherein the channel layer extends in the vertical direction to be disposed between the core insulating layer and the channel insulating layer,
wherein the first pad layer is disposed on top of the channel layer and between the core insulating layer and the channel insulating layer,
wherein the first polysilicon layer is disposed on top of the first pad layer and between the core insulating layer and the channel insulating layer, and
wherein a third vertical level of an upper surface of the core insulating layer is lower than a fourth vertical level of an upper surface of the first polysilicon layer.

20. A semiconductor memory device comprising:
a peripheral circuit structure disposed on a semiconductor substrate and including circuit elements;
a pattern structure disposed on the peripheral circuit structure, wherein the pattern structure includes a lower pattern layer, a middle pattern layer disposed on the lower pattern layer and including an impurity of a first conductivity, and an upper pattern layer disposed on the middle pattern layer;
a stack structure disposed on the pattern structure, wherein the stack structure includes a plurality of gate electrodes and a plurality of insulating layers each gate electrode of the plurality of gate electrodes and insulating layer of the plurality of insulating layers being alternately stacked on top of each other in a vertical direction;
a channel structure extending through the stack structure and extending in the vertical direction; and
a bit line connected to the channel structure via a contact plug disposed on the channel structure,
wherein the channel structure includes a core insulating layer, a channel layer disposed on a side surface of the core insulating layer, a channel insulating layer extending in the vertical direction to be disposed between the channel layer and the plurality of gate electrodes, and a channel pad disposed on top of the core insulating layer to be in contact with the channel layer,
wherein the channel pad includes:
a first pad layer including an impurity of a second conductivity different from the impurity of the first conductivity;
a second pad layer disposed on top of the first pad layer in the vertical direction, wherein the second pad layer includes an impurity of the first conductivity; and
a first polysilicon layer disposed between the first and second pad layers,
wherein the first polysilicon layer is not doped with an impurity, and
wherein an outermost side surface of the second pad layer is in contact with the channel insulating layer.
